(19) United States
(12) Patent Application Publication
(10) Pub. No.: US 2025/0193315 A1
(43) Pub. Date: Jun. 12, 2025

(54) COMMUNICATION DEVICE, COMMUNICATION METHOD, AND NON-TRANSITORY COMPUTER READABLE RECORDING MEDIUM STORING COMMUNICATION PROGRAM

(71) Applicant: Panasonic Intellectual Property Corporation of America, Torrance, CA (US)

(72) Inventors: Hiroki FURUKAWA, Osaka (JP); Kohhei Hayashida, Kyoto (JP); Yoshimasa Honda, Hyogo (JP); Yuta Shimotsuma, Osaka (JP)

(21) Appl. No.: 19/056,110

(22) Filed: Feb. 18, 2025

Related U.S. Application Data
(63) Continuation of application No. PCT/JP2023/026716, filed on Jul. 21, 2023.

(30) Foreign Application Priority Data
Aug. 22, 2022 (JP) 2022-131967

(51) Int. Cl. H04M 9/08; G10K 11/178; H03G 3/30

(52) U.S. Cl. CPC H04M 9/082; G10K 11/17854; H03G 3/3089

(57) ABSTRACT

A communication device includes: a first adder that adds a reproduction sound to a communication sound of a remote utterer and outputs the communication sound additionally including the reproduction sound to a speaker; and an acoustic echo canceler that cancels, on the basis of the communication sound to serve as a reference signal, an echo component of the communication sound contained in an input signal acquired by a microphone configured to collect a sound in a vicinity.

### FIELD OF INVENTION

The present disclosure relates to a technology of loudly producing a predetermined reproduction sound to a vicinity and enabling a person in the vicinity and a remote utterer to communicate with each other.

### BACKGROUND ART

For instance, Patent Literature 1 describes an acoustic echo canceler device with a loudly producing function. The device includes a sound detector that detects a level of a reception signal from a far-end and outputs a signal for suspending a modification of a coefficient to a coefficient modifier when the level of the reception signal indicates a given level or lower. That is to say, the modifier modifies the coefficient of an echo canceller only when receiving an input of a reception signal having the given level or higher.

Moreover, for instance, Patent Literature 2 describes a sound communication device having operability of resetting an acoustic echo cancelation function (adaptive filter) through a remote manipulation. The device thus enables confirmation as to whether sound data sent from its own terminal is appropriately reproduced at a destination terminal in sound communication via a communication network.

However, each conventional art makes it difficult for a remote utterer to confirm whether a reproduction sound is loudly produced, and thus still needs further improvement.

Patent Literature 1: Japanese Unexamined Patent Publication No. SHO 63-79449

Patent Literature 2: Japanese Patent Publication No. 5245884

### SUMMARY OF THE INVENTION

The present disclosure has been accomplished to overcome the drawbacks described above, and has an object of providing a technology that achieves cancelation of an acoustic echo attributed to loud producing of a communication sound of a remote utterer and enables the remote utterer to confirm whether the reproduction sound is loudly produced.

A communication device according to the present disclosure is a communication device that is configured to loudly produce a predetermined reproduction sound to a vicinity and enables a person in the vicinity and a remote utterer to communicate with each other. The communication device includes: a first adder that adds the reproduction sound to a communication sound of the remote utterer and outputs the communication sound additionally including the reproduction sound to a speaker; and an acoustic echo canceler that cancels, on the basis of the communication sound to serve as a reference signal, an echo component of the communication sound contained in an input signal acquired by a microphone configured to collect a sound in the vicinity.

The present disclosure achieves cancelation of an acoustic echo attributed to loud producing of a communication sound of a remote utterer, and enables remote utterer to confirm whether a reproduction sound is loudly produced.

### BRIEF DESCRIPTION OF THE DRAWINGS

FIG. 1 is a diagram showing a configuration of a communication system in a first embodiment of the present disclosure.

FIG. 2 is a block diagram showing a configuration of an acoustic echo canceler in the first embodiment of the disclosure in detail.

FIG. 3 is a flowchart explaining an operation by a communication device according to the first embodiment of the disclosure.

FIG. 4 is a diagram showing a configuration of a communication system in a second embodiment of the present disclosure.

FIG. 5 is a flowchart explaining an operation by a communication device according to the second embodiment of the disclosure.

FIG. 6 is a diagram showing a configuration of a communication system in a third embodiment of the present disclosure.

FIG. 7 is a flowchart explaining an operation by a communication device according to the third embodiment of the disclosure.

FIG. 8 is a diagram showing a configuration of a communication system in a fourth embodiment of the present disclosure.

FIG. 9 is a flowchart explaining an operation by a communication device according to the fourth embodiment of the disclosure.

FIG. 10 is a diagram showing a configuration of a communication system in a fifth embodiment of the present disclosure.

FIG. 11 is a graph showing a relation between a power value of a filter coefficient and a first lowering gain when a reproduction sound is detected in the fifth embodiment.

FIG. 12 is a first flowchart explaining an operation by a communication device according to the fifth embodiment of the disclosure.

FIG. 13 is a second flowchart explaining the operation by the communication device according to the fifth embodiment of the disclosure.

FIG. 14 is a diagram showing a configuration of a communication system in a sixth embodiment of the present disclosure.

FIG. 15 is a graph showing a relation between an echo cancelation amount and a first lowering gain when a reproduction sound is detected in the sixth embodiment.

FIG. 16 is a diagram showing a configuration of a communication system in a seventh embodiment of the present disclosure.

FIG. 17 is a flowchart explaining an operation by a communication device according to the seventh embodiment of the disclosure.

FIG. 18 is a diagram showing a configuration of a communication system in an eighth embodiment of the present disclosure.

FIG. 19 is a diagram showing a configuration of a communication system in a ninth embodiment of the present disclosure.

FIG. 20 is a diagram showing a configuration of a communication system in a tenth embodiment of the present disclosure.

FIG. 21 is a diagram showing a configuration of a communication system in an eleventh embodiment of the present disclosure.

FIG. 22 is a diagram showing a configuration of: a vehicle including the communication device according to the first embodiment; and a remote supervising device.

FIG. 23 is a diagram showing another configuration of: a vehicle including the communication device according to the first embodiment; and a remote supervising device.

### DETAILED DESCRIPTION

### Knowledge Forming the Basis of the Present Disclosure

A conventional transportation system makes a vehicle transport an article, the vehicle being configured to autonomous travel and to travel under remote control. In the transportation system, a remote supervisor remotely controls a movement of the vehicle, and the remote supervisor and a recipient to receive the article are required to communicate with each other. The vehicle includes a speaker, a microphone, and an acoustic echo canceler, and the recipient of the article communicates with the remote supervisor through loud sound production. The speaker loudly produces a communication sound of the remote supervisor, and the microphone collects an uttering sound of the recipient. The acoustic echo canceler cancels an echo component of the communication sound of the remote supervisor contained in an input signal acquired by the microphone.

The vehicle further loudly reproduces a reproduction sound saying, for example, “the vehicle leaves” or “the vehicle moves backward”, to draw attention of a person in a vicinity. The remote supervisor starts to move the vehicle after giving an instruction of the loud producing of the reproduction sound. The remote supervisor is thus required to confirm that the reproduction sound is loudly produced from the vehicle and that the loud producing of the reproduction sound is finished.

In this regard, in Patent Literature 1, a reproduction sound coming from the speaker to the microphone is removed as an acoustic echo as well as a reception signal coming from the speaker to the microphone in a case where the speaker loudly produces the reproduction sound together with the reception signal at a far-end. Hence, the reproduction sound is inaudible to the remote supervisor, and the remote supervisor faces difficulty in confirming whether the reproduction sound is appropriately loudly produced.

Further, in Patent Literature 2, a filter coefficient is reset to allow one's own terminal to confirm loud producing of a sound at a destination terminal without removing an echo coming from a speaker to a microphone by an cancelation way. However, the echo coming from the speaker to the microphone is removed in progress of an update of the filter coefficient by the echo canceling way. This may lead to a failure at confirming a finish of loud producing of a reproduction sound depending on a length of the reproduction sound.

Additionally, in Patent Literature 2, a sound signal and the reproduction sound of the one's own terminal are transmitted from the destination terminal. This may make the reproduction sound be superimposed on the sound signal of the one's own terminal and make the reproduction sound inaudible, resulting in a failure at confirming whether the reproduction sound is loudly produced in an appropriate manner.

The following technologies will be described to overcome the drawbacks.
(1) A communication device according to one aspect of the present disclosure is a communication device that is configured to loudly produce a predetermined reproduction sound to a vicinity and enables a person in the vicinity and a remote utterer to communicate with each other. The communication device includes: a first adder that adds the reproduction sound to a communication sound of the remote utterer and outputs the communication sound additionally including the reproduction sound to a speaker; and an acoustic echo canceler that cancels, on the basis of the communication sound to serve as a reference signal, an echo component of the communication sound contained in an input signal acquired by a microphone configured to collect a sound in the vicinity.

In this configuration, the acoustic echo canceler receives the communication sound of the remote utterer to serve as a reference signal, and the acoustic echo canceler avoids receiving the reproduction sound as the reference signal. Accordingly, an echo component of the communication sound is canceled by the acoustic echo canceler from the communication sound additionally including the reproduction sound coming from the speaker to the microphone, but an echo component of the reproduction sound is output toward the remote utterer without being canceled.

The configuration hence achieves cancelation of an acoustic echo attributed to loud producing of the communication sound of the remote utterer, and enables the remote utterer to confirm whether the reproduction sound is loudly produced.
(2) The communication device according to (1) above may further include a reproduction sound detector that detects presence or absence of the reproduction sound. The acoustic echo canceler may suspend an update of a filter coefficient of an adaptive filter when the reproduction sound detector detects the reproduction sound.

This configuration avoids the update of the filter coefficient of the adaptive filter when the reproduction sound is detected, and thus enables accurate cancelation of only the echo component of the communication sound of the remote utterer.
(3) The communication device according to (1) or (2) above may further include a first sound volume adjuster that adjusts a sound volume of the reproduction sound and outputs the reproduction sound having the adjusted sound volume to the first calculator.

This configuration in which the speaker outputs the reproduction sound having the adjusted sound volume and the communication sound allows the reproduction sound to be reliably audible to a person in the vicinity of the speaker.
(4) The communication device according to any one of (1) to (3) above may further include an automatic gain controller that automatically adjusts a sound volume indicated by an output signal from the acoustic echo canceler.

This configuration achieves automatic adjustment of the sound volume indicated by the output signal from the acoustic echo canceler. The configuration thus allows a sound volume of an echo of the reproduction sound and a sound volume of an uttering sound of a near-end utterer in the vicinity of the microphone to agree with each other in such a manner that both the echo of the reproduction sound and the uttering sound of the near-end utterer are easily audible to the remote utterer.
(5) The communication device according to (2) above may further include: a lowering gain setter that sets a first lowering gain for lowering a sound volume indicated by an output signal from the acoustic echo canceler when the reproduction sound detector detects the reproduction sound, and sets a second lowering gain for avoiding the lowering of the sound volume indicated by the output signal from the acoustic echo canceler when the reproduction sound detector does not detect the reproduction sound; and a variable amplifier that multiplies the output signal from the acoustic echo canceler by the first lowering gain or the second lowering gain set by the lowering gain setter.

This configuration includes setting the first lowering gain to be multiplied by an output signal from the acoustic echo canceler so that a sound volume of an echo of the reproduction sound which is audible to the remote utterer and a sound volume of an uttering sound of a near-end utterer are equal to each other when the reproduction sound is detected. Consequently, the configuration allows the sound volume of the echo of the reproduction sound and the sound volume of the uttering sound of the near-end utterer in the vicinity of the microphone to agree with each other in such a manner that both the echo of the reproduction sound and the uttering sound of the near-end utterer are easily audible to the remote utterer.
(6) The communication device according to (1) above may further include: a sound volume lowering part that lowers a sound volume of the reproduction sound; and a second adder that adds the reproduction sound having the sound volume lowered by the sound volume lowering part to the communication sound. The acoustic echo canceler may cancel, on the basis of an output signal from the second adder to be a reference signal, the echo component of the communication sound and echo component of the reproduction sound having the lowered sound volume contained in the input signal acquired by the microphone.

In this configuration, a sound volume of the reproduction sound output from the speaker differs from a sound volume of the reproduction sound input into the acoustic echo canceler to serve as the reference signal. Hence, an echo component in a part of the reproduction sound is output without being canceled by the acoustic echo canceler. The configuration accordingly enables the remote utterer to confirm whether the reproduction sound is loudly produced.
(7) The communication device according to (6) above may further include a reproduction sound detector that detects presence or absence of the reproduction sound. The acoustic echo canceler may suspend an update of a filter coefficient of an adaptive filter when the reproduction sound detector detects the reproduction sound.

This configuration avoids the update of the filter coefficient of the adaptive filter when the reproduction sound is detected, and thus enables accurate cancelation of only the echo component of the communication sound of the remote utterer.
(8) The communication device according to (7) above may further include: a lowering gain setter that estimates an echo cancelation amount of the acoustic echo canceler and sets a first lowering gain for lowering a sound volume indicated by an output signal from the acoustic echo canceler in association with the estimated echo cancelation amount when the reproduction sound detector detects the reproduction sound, and sets a second lowering gain for avoiding the lowering of the sound volume indicated by the output signal from the acoustic echo canceler when the reproduction sound detector does not detect the reproduction sound; and a variable amplifier that multiplies the output signal from the acoustic echo canceler by the first lowering gain or the second lowering gain set by the lowering gain setter.

This configuration includes setting the first lowering gain to be multiplied by an output signal from the acoustic echo canceler, depending on a situation of removal of an echo by the acoustic echo canceler, so that a sound volume of an echo of the reproduction sound and a sound volume of an uttering sound of a near-end utterer which are audible to the remote utterer are equal to each other when the reproduction sound is detected. Consequently, the configuration allows the sound volume of the echo of the reproduction sound and the sound volume of the uttering sound of the near-end utterer in the vicinity of the microphone to agree with each other in such a manner that both the echo of the reproduction sound and the uttering sound of the near-end utterer are easily audible to the remote utterer.
(9) In the communication device according to (8) above, the lowering gain setter may calculate a power value of the filter coefficient and estimate the echo cancelation amount from the calculated power value of the filter coefficient.

In this configuration, when the filter coefficient is not updated and the filter coefficient has a small power value, the echo cancelation amount reduces and the sound volume of the echo of the reproduction sound output from the acoustic echo canceler increases. Hence, the echo component of the reproduction sound is suppressed or lowered with the first lowering gain until the power value of the filter coefficient increases in progress of the update of the filter coefficient. Consequently, the configuration allows the sound volume of the echo of the reproduction sound and a sound volume of an uttering sound of a near-end utterer in the vicinity of the microphone to agree with each other in such a manner that both the echo of the reproduction sound and the uttering sound of the near-end utterer are easily audible to the remote utterer.
(10) In the communication device according to (8) above, the lowering gain setter may estimate the echo cancelation amount on the basis of a level of the input signal input into the acoustic echo canceler from the microphone and a level of the output signal from the acoustic echo canceler.

In this configuration, the echo cancelation amount shows, for example, a ratio between the level of the input signal input into the acoustic echo canceler from the microphone and the level of the output signal from the acoustic echo canceler. When the acoustic echo canceler does not cancel the echo, the echo cancelation amount reaches “1” and the sound volume of the echo of the reproduction sound output from the acoustic echo canceler increases. Hence, the echo component of the reproduction sound is suppressed or lowered with the first lowering gain until the acoustic echo canceler satisfactorily cancels the echo. Consequently, the configuration allows the sound volume of the echo of the reproduction sound and a sound volume of an uttering sound of a near-end utterer in the vicinity of the microphone to agree with each other in such a manner that both the echo of the reproduction sound and the uttering sound of the near-end utterer are easily audible to the remote utterer.
(11) In the communication device according to (1) above, the acoustic echo canceler may cancel, on the basis of an output signal from the first adder to be a reference signal, the echo component of the communication sound and an echo component of the reproduction sound contained in the input signal acquired by the microphone. The communication device may further include a second adder that adds the reproduction sound to an output signal from the acoustic echo canceler.

In this configuration, the acoustic echo canceler removes the echo component of the reproduction sound coming from the speaker to the microphone. Then, the reproduction sound is added to the output signal from the acoustic echo canceler excluding the echo component of the reproduction sound, and an output signal additionally including the reproduction sound having not passed through an acoustic echo route is output toward the remote utterer. This enables the remote utterer to confirm a clear reproduction sound without an acoustic echo.
(12) The communication device according to (11) above may further include a second sound volume adjuster that adjusts a sound volume of the reproduction sound. The second adder may add the reproduction sound having the sound volume adjusted by the second sound volume adjuster to the output signal from the acoustic echo canceler.

This configuration achieves adjustment of the sound volume of the reproduction sound to be added to the output signal from the acoustic echo canceler. Consequently, the configuration allows the sound volume of the reproduction sound and a sound volume of an uttering sound of a near-end utterer in the vicinity of the microphone to agree with each other in such a manner that both the reproduction sound and the uttering sound of the near-end utterer are easily audible to the remote utterer.
(13) The communication device according to any one of (1) to (3) above may further include a switch that switches, on the basis of a control signal indicating whether to return the communication sound to a remote location, between an ON-mode of inputting the communication sound as the reference signal into the acoustic echo canceler and an OFF-mode of avoiding the inputting of the communication sound as the reference signal into the acoustic echo canceler. The switch may switch to the OFF-mode when the control signal indicates returning of the communication sound to the remote location.

In this configuration, when the control signal indicates returning of the communication sound to the remote location, the switch switches to the OFF-mode of avoiding the inputting of the communication sound as the reference signal into the acoustic echo canceler. The configuration thus keeps the acoustic echo canceler from removing the communication sound and enables the remote utterer to confirm that the communication sound of the remote utterer is loudly produced at a destination.
(14) The communication device according to any one of (1) to (3) above may further include: a third adder that adds the communication sound to an output signal from the acoustic echo canceler; and a third sound volume adjuster that adjusts, on the basis of a control signal indicating whether to return the communication sound to a remote location, a sound volume of the communication sound to be input into the third adder. The third sound volume adjuster may adjust the communication sound to a sound volume which is audible to the remote utterer when the control signal indicates returning of the communication sound to the remote location, and may adjust the communication sound to a sound volume which is inaudible to the remote utterer when the control indicates avoiding the returning of the communication sound to the remote location.

This configuration achieves adjustment of the communication sound to a sound volume which is audible to the remote utterer when the control signal indicates returning of the communication sound to the remote location. The configuration in which the communication sound having the sound volume adjusted to be audible to the remote utterer by the third sound volume adjuster is added to the output signal from the acoustic echo canceler enables the remote utterer to confirm that the communication sound of the remote utterer is loudly produced at a destination.
(15) The communication device according to (11) or (12) above may further include a switch that switches, on the basis of a control signal indicating whether to return the communication sound to a remote location, between an ON-mode of inputting an output signal from the first adder as the reference signal into the acoustic echo canceler and an OFF-mode of avoiding the inputting of the output signal from the first adder as the reference signal into the acoustic echo canceler. The switch may switch to the OFF-mode when the control signal indicates returning of the communication sound to the remote location.

In this configuration, when the control signal indicates returning of the communication sound to the remote location, the switch switches to the OFF-mode of avoiding the inputting of the output signal from the first adder as the reference signal into the acoustic echo canceler. The configuration thus keeps the acoustic echo canceler from removing the communication sound and enables the remote utterer to confirm that the communication sound of the remote utterer is loudly produced at a destination.
(16) The communication device according to (11) or (12) above may further include: a third adder that adds the communication sound to an output signal from the second adder; and a third sound volume adjuster that adjusts, on the basis of a control signal indicating whether to return the communication sound to a remote location, a sound volume of the communication sound to be input into the third adder. The third sound volume adjuster may adjust the communication sound to a sound volume which is audible to the remote utterer when the control signal indicates returning of the communication sound to the remote location, and may adjust the communication sound to a sound volume which is inaudible to the remote utterer when the control indicates avoiding the returning of the communication sound to the remote location.

This configuration achieves adjustment of the communication sound to a sound volume which is audible to the remote utterer when the control signal indicates returning of the communication sound to the remote location. The configuration in which the communication sound having the sound volume adjusted to be audible to the remote utterer by the third sound volume adjuster is added to the output signal from the second adder enables the remote utterer to confirm that the communication sound of the remote utterer is loudly produced at a destination.
(17) The communication device according to any one of (1) to (16) above may further include: a storage part that stores a plurality of the reproduction sounds in advance; a communicator that receives, from a remote communication device, reproduction information designating a reproduction sound to be output among the reproduction sounds; and a reader that reads out the reproduction sound designated by the reproduction information from the storage part.

The configuration enables reading-out of a reproduction sound stored by the communication device, and allows the speaker to output the read out reproduction sound.
(18) The communication device according to any one of (1) to (16) above may further include a communicator that receives the reproduction sound sent from a remote communication device.

The configuration enables receiving of the reproduction sound from the remote communication device and outputting of the received reproduction sound from the speaker.

Moreover, the disclosure can be realized as: a communication device including the above-described distinctive configuration; and a communication method executing distinctive ways each corresponding to the distinctive configuration of the communication device. Additionally, the disclosure can be realized by a computer program causing a computer to execute the distinctive ways included in the communication method. From these perspectives, the same advantageous effects as those of the communication device are achievable in the following other aspects.
(19) A communication method according to another aspect of the present disclosure is a communication method for a communication device that is configured to loudly produce a predetermined reproduction sound to a vicinity and enables a person in the vicinity and a remote utterer to communicate with each other. The communication method includes: adding the reproduction sound to a communication sound of the remote utterer and outputting the communication sound additionally including the reproduction sound to a speaker; and canceling, on the basis of the communication sound to serve as a reference signal, an echo component of the communication sound contained in an input signal acquired by a microphone configured to collect a sound in the vicinity.
(20) A communication program according to further another aspect of the present disclosure is a communication program for loudly producing a predetermined reproduction sound to a vicinity and enabling a person in the vicinity and a remote utterer to communicate with each other. The communication program includes causing a computer to serve as: a first adder that adds the reproduction sound to a communication sound of the remote utterer and outputs the communication sound additionally including the reproduction sound to a speaker; and an acoustic echo canceler that cancels, on the basis of the communication sound to serve as a reference signal, an echo component of the communication sound contained in an input signal acquired by a microphone configured to collect a sound in the vicinity.
(21) A non-transitory computer readable recording medium that records a communication program according to still another aspect of the present disclosure is a non-transitory computer readable recording medium that records a communication program for loudly producing a predetermined reproduction sound to a vicinity and enabling a person in the vicinity and a remote utterer to communicate with each other. The non-transitory computer readable recording medium includes causing a computer to serve as: a first adder that adds the reproduction sound to a communication sound of the remote utterer and outputs the communication sound additionally including the reproduction sound to a speaker; and an acoustic echo canceler that cancels, on the basis of the communication sound to serve as a reference signal, an echo component of the communication sound contained in an input signal acquired by a microphone configured to collect a sound in the vicinity.

Embodiments of this disclosure will be described with reference to the accompanying drawings. Each of the embodiments which will be described below represents a specific example of the disclosure. Numeric values, shapes, constituent elements, steps, and the order of the steps described below in each embodiment are mere examples, and thus should not be construed to delimit the disclosure. Moreover, constituent elements which are not recited in the independent claims each showing the broadest concept among the constituent elements in the embodiments are described as selectable constituent elements. The respective contents are combinable with each other in all the embodiments.

### First Embodiment

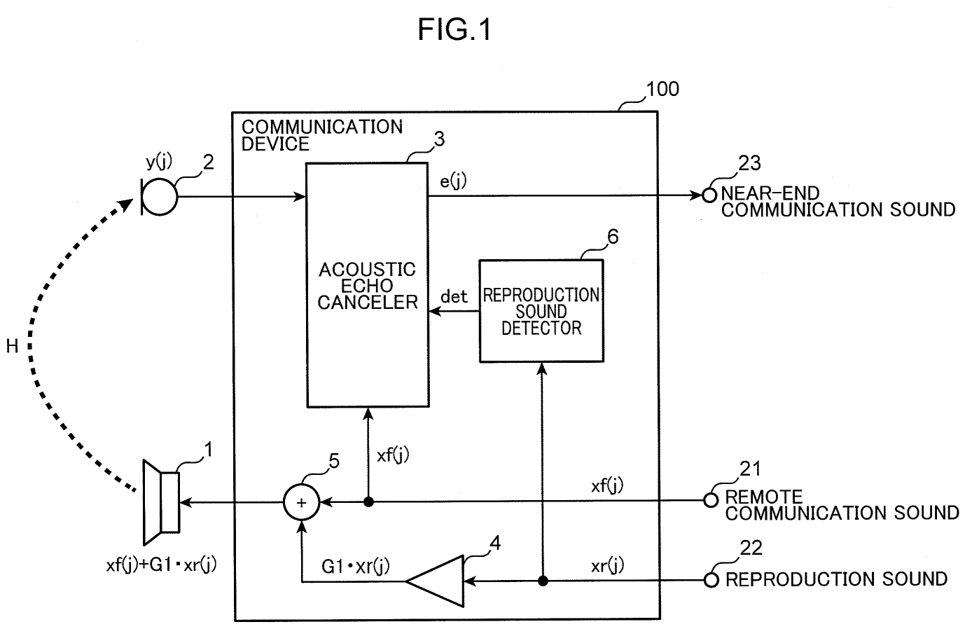

FIG. 1 is a diagram showing a configuration of a communication system in the first embodiment of the present disclosure.

The communication system is mountable to a vehicle. The vehicle is, for example, an electric robot, an electric vehicle, an electric truck, or an electric drone. For instance, the vehicle moves within a predetermined region to transport an article of a user. The vehicle is supervised by a remote supervisor. The vehicle is configured to autonomously travel and to travel under remote control.

The communication system shown in FIG. 1 includes a speaker 1, a microphone 2, a communication sound input part 21, a reproduction sound input part 22, a communication sound output part 23, and a communication device 100.

The communication device 100 is configured to loudly produce a predetermined reproduction sound to a vicinity and enables a person in the vicinity and a remote supervisor to communicate with each other. The remote supervisor serves as an example remote utterer. The reproduction sound includes a sound or voice saying, for example, “the vehicle leaves” or “the vehicle moves backward”, to draw attention of the person in the vicinity. For instance, the reproduction sound is loudly produced when the vehicle starts to move.

The communication sound input part 21 receives a remote communication sound of the remote supervisor from a remote supervising device (not shown) at a receiver, and outputs the remote communication sound to the communication device 100.

The reproduction sound input part 22 outputs the reproduction sound to the communication device 100.

The speaker 1 loudly produces the remote communication sound of the remote supervisor and loudly produces the reproduction sound. Here, when the microphone 2 collects the sound output from the speaker 1, a speaker at the receiver reproduces a sound uttered by an utterer at the receiver in delay. As a result, a so-called acoustic echo occurs. In this regard, an acoustic echo canceler 3 to be described later suppresses an acoustic echo signal contained in an input signal output from the microphone 2.

The microphone 2 is configured to collect a sound or voice in a vicinity. The microphone 2 collects a sound or voice of a near-end utterer (sender). The microphone 2 outputs an input signal indicating the collected sound to the communication device 100.

The communication device 100 includes the acoustic echo canceler 3, a first amplifier 4, a first adder 5, and a reproduction sound detector 6. The communication device 100 may include at least one of the speaker 1 and the microphone 2.

The acoustic echo canceler 3 cancels, on the basis of the remote communication sound of the remote supervisor to serve as a reference signal, an echo component of the remote communication sound contained in the input signal acquired by the microphone 2. The acoustic echo canceler 3 receives an input of a remote communication sound xf(j) to serve as the reference signal and an input of an input signal y(j) from the microphone 2. The acoustic echo canceler 3 removes an acoustic echo attributed to the remote communication sound loudly produced by the speaker 1 and coming to the microphone 2. The acoustic echo canceler 3 outputs an echo removal signal e(j) excluding the echo component of the remote communication sound xf(j) from the input signal y(j) acquired by the microphone 2. A configuration of the acoustic echo canceler 3 will be described in detail later.

The first amplifier 4 controls a sound volume of the reproduction sound in such a manner that the reproduction sound is audible in a loud sound required area. The first amplifier 4 serves as an example first sound volume adjuster. The first amplifier 4 adjusts the sound volume of the reproduction sound and outputs the reproduction sound having the adjusted sound volume to the first adder 5.

The first adder 5 adds the reproduction sound output from the first amplifier 4 to the remote communication sound output from the communication sound input part 21. The first adder 5 adds the reproduction sound to the remote communication sound of the remote utterer, and outputs the communication sound additionally including the reproduction sound to the speaker 1.

The remote communication sound xf(j) serves as a reference signal for the acoustic echo canceler 3. The first amplifier 4 multiplies a reproduction sound xr(j) by a predetermined gain G1. The gain G1 is determined in advance depending on an environment for use of the communication device 100. The gain G1 has a value larger than “0”. The first adder 5 adds “G1·xr(j)” to the remote communication sound xf(j). The speaker 1 loudly produces “xf(j)+G1·xr(j)”. The acoustic echo canceler 3 deduces an impulse response H to reach the microphone 2 from the speaker 1.

The reproduction sound detector 6 detects presence or absence of the reproduction sound xr(j). The reproduction sound detector 6 calculates an amplitude level xr^{˜}(j) of the reproduction sound xr(j) by short-time averaging processing for the amplitude as expressed by the following Equation (1). The reproduction sound detector 6 determines whether the amplitude level xr^{˜}(j) is higher than a threshold.

$${xr}^{∼} ( j ) = B \cdot \vert xr ( j ) \vert + ( 1 - B ) \cdot {xr}^{∼} ( j - 1 ) \qquad ( 1 )$$

In Equation (1), the sign “|xr(j)|” denotes an absolute value of the reproduction sound xr(j), the sign “xr^{˜}(j)” denotes a short-time averaging value of absolute values of the reproduction sound xr(j), the sign “j” denotes a time, and the sign “B” denotes an update gain (0<B<1).

The reproduction sound detector 6 determines presence of a reproduction sound when the amplitude level is higher than the threshold. In contrast, the reproduction sound detector 6 determines absence of the reproduction sound when the amplitude level is equal to or lower than the threshold.

The acoustic echo canceler 3 deduces an impulse response to reach the microphone 2 from the speaker 1 when the reproduction sound detector 6 does not detect a reproduction sound. The acoustic echo canceler 3 suspends the deduction of the impulse response to reach the microphone 2 from the speaker 1 when the reproduction sound detector 6 detects a reproduction sound. In other words, the acoustic echo canceler 3 suspends an update of a filter coefficient of an adaptive filter when the reproduction sound detector 6 detects a reproduction sound.

The communication sound output part 23 outputs the echo removal signal e(j) output from the acoustic echo canceler 3 to serve as a near-end communication sound.

The communication sound input part 21, the reproduction sound input part 22, and the communication sound output part 23 are connected to a communicator (not shown). The communicator is configured to send the near-end communication sound to the remote supervising device (not shown) at the receiver via a network and receive a remote communication sound from the remote supervising device (not shown) at the receiver via the network. The communicator is further configured to receive a reproduction sound from the remote supervising device (not shown) at the receiver via the network. The network includes, for example, the internet.

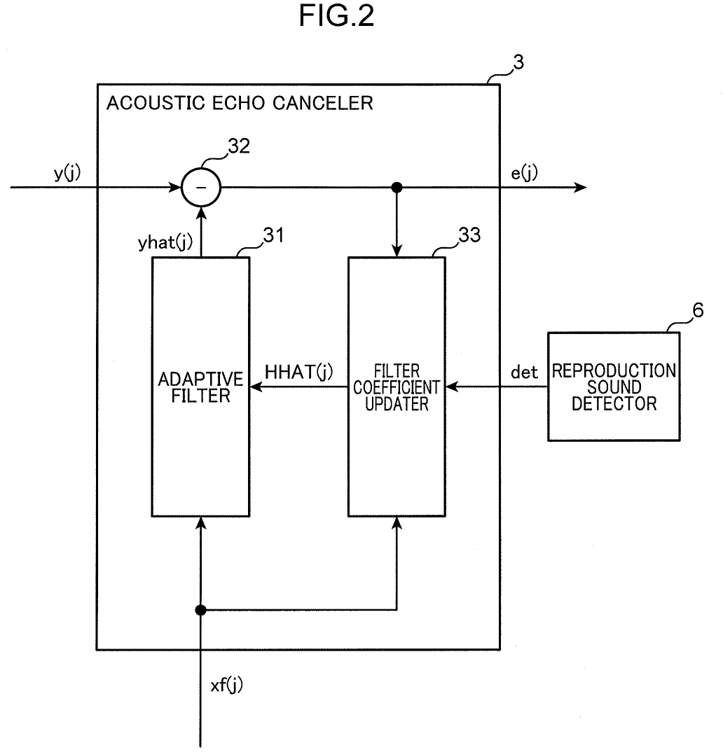

FIG. 2 is a block diagram showing a configuration of the acoustic echo canceler 3 in the first embodiment of the disclosure in detail.

The acoustic echo canceler 3 includes an adaptive filter 31, a subtractor 32, and a filter coefficient updater 33.

The adaptive filter 31 generates a deduced echo yhat(j) through convolution of a filter coefficient HHAT(j) and a reference signal series Xf(j).

The subtractor 32 subtracts the deduced echo yhat(j) from the input signal y(j) from the microphone 2 to remove an echo component of the remote communication sound xj(j) contained in the input signal y(j). The subtractor 32 outputs the echo removal signal e(j) excluding the echo component from the input signal y(j).

The filter coefficient updater 33 updates the filter coefficient HHAT(j) by utilzing the echo removal signal e(j) output from the subtractor 32 and the reference signal series Xf(j).

The input signal y(j) output from the microphone 2 is expressed with the following Equation (2) including the input signal series Xf(j)+G1·Xr(j) of the speaker 1 and an impulse response H in an acoustic echo route from the speaker 1 to the microphone 2.

$$y ( j ) = H * ( Xf ( j ) + G 1 \cdot Xr ( j ) ) \qquad ( 2 )$$

In Equation (2), the values of “Xf(j)”, “Xr(j)”, and “H” are respectively expressed with the following Equation (3), Equation (4), and Equation (5). In Equation (2), the sign “*” denotes a convolution operation.

$$Xf ( j ) = xf ( j ) , xf ( j - 1 ) , … , xf ( j - N + 1 ) \qquad ( 3 )$$

$$Xr ( j ) = xr ( j ) , xr ( j - 1 ) , … , xr ( j - N + 1 ) \qquad ( 4 )$$

$$H = h ( 0 ) , h ( 1 ) , … , h ( N - 1 ) \qquad ( 5 )$$

In Equation (3), Equation (4), and Equation (5), the sign “N” denotes a filter tap length.

Here, the number of taps for the impulse response H is defined as the same as the number of taps for the filter coefficient HHAT(j) of the acoustic echo canceler 3. Actually, the impulse response attenuates as a time elapses. In this respect, when the acoustic echo canceler 3 enables satisfactory removal of the acoustic echo, the number of taps for the impulse response H can be defined as the number of taps for the filter coefficient HHAT(j) without any practical problem.

The deduced echo yhat(j) generated by the adaptive filter 31 is expressed with the following Equation (6).

$$yhat ( j ) = HHAT ( j ) * Xf ( j ) \qquad ( 6 )$$

In Equation (6), the filter coefficient “HHAT(j)” is expressed with the following Equation (7).

$$HHAT ( j ) = hhat ( j , 0 ) , hhat ( j , 1 ) , … , hhat ( j , N - 1 ) \qquad ( 7 )$$

The echo removal signal e(j) output from the subtractor 32 is expressed with the following Equation (8).

$$\begin{matrix}e ( j ) = y ( j ) - yhat ( j ) \\ = H * ( Xf ( j ) + G 1 \cdot Xr ( j ) ) - HHAT ( j ) * Xf ( j ) \\ = ( H - HHAT ( j ) ) * Xf ( j ) + G 1 \cdot H * Xr ( j )\end{matrix} \qquad ( 8 )$$

When the reproduction sound detector 6 does not detect the reproduction sound, the filter coefficient HHAT(j) updated by the filter coefficient updater 33 is expressed with the following Equation (9).

$$HHAT ( j + 1 ) = HHAT ( j ) + Δ \cdot Xf ( j ) \qquad ( 9 )$$

Here, the value of “Δ” in Equation (9) is expressed with the following Equation (10).

$$Δ = α \cdot e ( j ) / ‖ Xf ( j ) ‖ \qquad ( 10 )$$

Further, the sign “∥Xf(j)∥” in Equation (10) denotes a norm of “Xf(j)” and the value thereof is expressed with the following Equation (11). The sign “α” denotes a gain (0≤α≤1).

$$‖ Xf ( j ) ‖ = {xf ( j )}^{2} + {xf ( j - 1 )}^{2} + … + {xf ( j - N + 1 )}^{2} \qquad ( 11 )$$

Equation (9) employs a normalized mean least squares algorithm as an algorithm for the update of the coefficient, but may employ another algorithm as the algorithm for the update of the coefficient.

When the reproduction sound detector 6 detects a reproduction sound, the filter coefficient HHAT(j) whose update by the filter coefficient updater 33 is suspended is expressed with the following Equation (12).

$$HHAT ( j + 1 ) = HHAT ( j ) \qquad ( 12 )$$

A whole area is processed at once concerning Equation (2) to Equation (12), but a plurality of bands resulting from dividing the whole area may be processed. In each of Equation (2) to Equation (12), the processing is based on a time domain, but may be based on a frequency domain.

Correct deduction of the impulse response H in the actual acoustic echo route with the filter coefficient HHAT(j) of the acoustic echo canceler 3 provides “HHAT(j)≈H”. The reference signal for the acoustic echo canceler 3 reaches “Xf(j)” in the case of the reproduction sound series Xr(j)=0. In Equation (8), in the case of “HHAT(j)≈H” and “Xr(j)=0”, the echo removal signal e(j) output from the acoustic echo canceler 3 results in “e(j)≈0”. This consequently achieves removal of the echo.

Subsequently, an operation by the communication device 100 according to the first embodiment of the disclosure will be described.

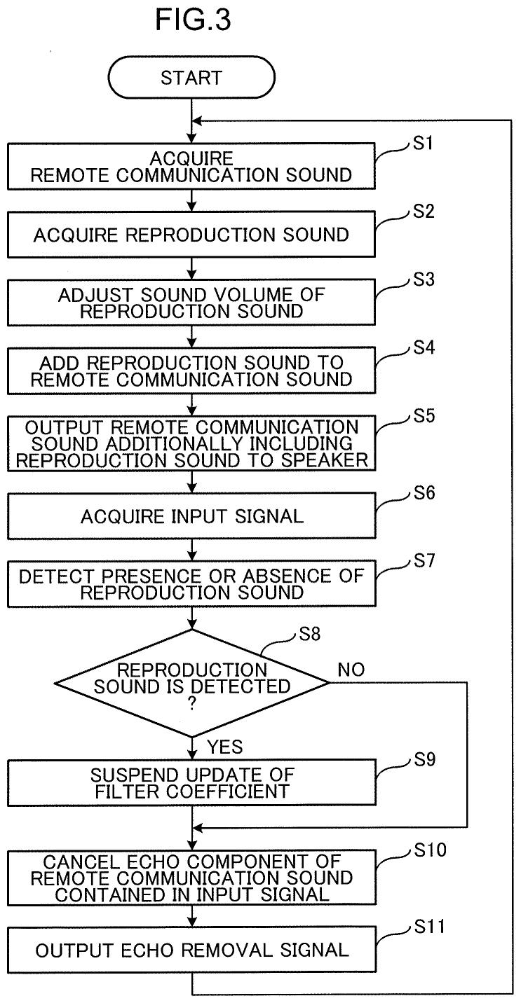

FIG. 3 is a flowchart explaining the operation by the communication device 100 according to the first embodiment of the disclosure.

First, in step S1, each of the acoustic echo canceler 3 and the first adder 5 acquires a remote communication sound output from the communication sound input part 21. The communication sound input part 21 outputs the remote communication sound received from a remote supervising device (not shown) at a receiver to each of the acoustic echo canceler 3 and the first adder 5. The acoustic echo canceler 3 acquires only the remote communication sound as a reference signal.

Next, in step S2, the first amplifier 4 acquires a reproduction sound output from the reproduction sound input part 22. The reproduction sound input part 22 outputs the reproduction sound received from the remote supervising device (not shown) at the receiver to the first amplifier 4.

Then, in step S3, the first amplifier 4 adjusts a sound volume of the reproduction sound. The first amplifier 4 multiplies the reproduction sound by a predetermined gain G1. The first amplifier 4 outputs the reproduction sound having the adjusted sound volume to the first adder 5.

Thereafter, in step S4, the first adder 5 adds the reproduction sound having the sound volume adjusted by the first amplifier 4 to the remote communication sound.

Further, in step S5, the first adder 5 outputs the remote communication sound additionally including the reproduction sound to the speaker 1. The speaker 1 loudly produces the remote communication sound additionally including the reproduction sound.

Next, in step S6, the acoustic echo canceler 3 acquires an input signal from the microphone 2. At this time, the microphone 2 collects a sound in a vicinity and outputs the input signal to the acoustic echo canceler 3. The input signal includes a sound uttered by a near-end utterer and the remote communication sound additionally including the reproduction sound coming from the speaker 1 to the microphone 2.

Then, in step S7, the reproduction sound detector 6 detects presence or absence of the reproduction sound.

Thereafter, in step S8, the reproduction sound detector 6 determines whether the reproduction sound is detected. When it is determined that the reproduction sound is not detected (NO in step S8), the process proceeds to step S10. The reproduction sound detector 6 outputs, to the acoustic echo canceler 3, a detection result signal det indicating whether the reproduction sound is detected.

In contrast, when it is determined that the reproduction sound is detected (YES in step S8), the acoustic echo canceler 3 suspends an update of a filter coefficient of the adaptive filter 31 in step S9.

Next, in step S10, the acoustic echo canceler 3 cancels, on the basis of the remote communication sound to serve as the reference signal, an echo component of the remote communication sound contained in the input signal acquired by the microphone 2.

Subsequently, in step S11, the acoustic echo canceler 3 outputs an echo removal signal excluding the echo component of the remote communication sound from the input signal. The acoustic echo canceler 3 outputs the echo removal signal to the communication sound output part 23. The communication sound output part 23 sends, to the remote supervising device (not shown) at the receiver, the echo removal signal output from the acoustic echo canceler 3 to serve as a near-end communication sound.

Conclusively, the acoustic echo canceler 3 receives the communication sound of a remote utterer to serve as a reference signal, and the acoustic echo canceler 3 avoids receiving the reproduction sound as the reference signal. Accordingly, an echo component of the communication sound is canceled by the acoustic echo canceler 3 from the communication sound additionally including the reproduction sound coming from the speaker 1 to the microphone 2, but an echo component of the reproduction sound is output toward the remote utterer without being canceled. The configuration hence achieves cancelation of an acoustic echo attributed to loud producing of the communication sound of the remote utterer, and enables the remote utterer to confirm whether the reproduction sound is loudly produced.

In the configuration in FIG. 1, a remote communication sound xf(j) is loudly produced by the speaker 1, and at the same time, is input into the acoustic echo canceler 3 to serve as a reference signal series Xf(j). The remote communication sound xf(j) comes from the speaker 1 to the microphone 2. The adaptive filter 31 in the acoustic echo canceler 3 generates a deduced echo yhat(j) through convolution of a reference signal series Xf(j) and a deduced filter coefficient HHAT(j). The echo component of the remote communication sound xf(j) is removed from an input signal y(j) output from the microphone 2 by subtracting the generated deduced echo yhat(j) from the input signal y(j).

A reproduction sound xr(j) having a sound volume adjusted by the first amplifier 4 is added to the remote communication sound xf(j) by the first adder 5. The reproduction sound xr(j) added to the remote communication sound xf(j) is loudly produced by the speaker 1 and collected by the microphone 2. The reproduction sound xr(j) is not included in the reference signal series Xf(j) for the acoustic echo canceler 3. Thus, the deduced echo yhat(j) does not contain an echo component H*G1·Xr(j) of the reproduction sound. The echo component of the reproduction sound xr(j) is sent to the remote supervising device without being removed by the acoustic echo canceler 3. In other words, the echo component of the remote communication sound xf(j) is removed, but the echo component of the reproduction sound xr(j) is not removed. This allows the acoustic echo of the reproduction sound xr(j) to be audible to the remote supervisor.

In the first embodiment, the communication device 100 may exclude the reproduction sound detector 6. In the first embodiment, the communication device 100 may further exclude the first amplifier 4.

### Second Embodiment

For example, a sound volume of a reproduction sound to encourage a person in a vicinity of a vehicle to pay attention is set to a large value in such a manner that the reproduction sound is reliably audible to the person in the vicinity. In this example, a sound volume of a reproduction sound collected by the microphone 2 may be larger than a sound volume of an uttering sound of a near-end utterer in the vicinity. Besides, when a distance between the speaker 1 and the microphone 2 is short, the sound volume of the reproduction sound collected by the microphone 2 is much larger. In the communication device 100 in the first embodiment, a sound volume of a reproduction sound may be larger than a sound volume of an uttering sound of a near-end utterer in the vicinity. Such a difference between the sound volumes of the two sounds may make it difficult to allow an echo of the reproduction sound and the uttering sound to be audible. In this regard, a communication device according to the second embodiment performs automatic adjustment of a gain so that a sound volume indicated by an echo removal signal output from an acoustic echo canceler 3 does not exceed a threshold.

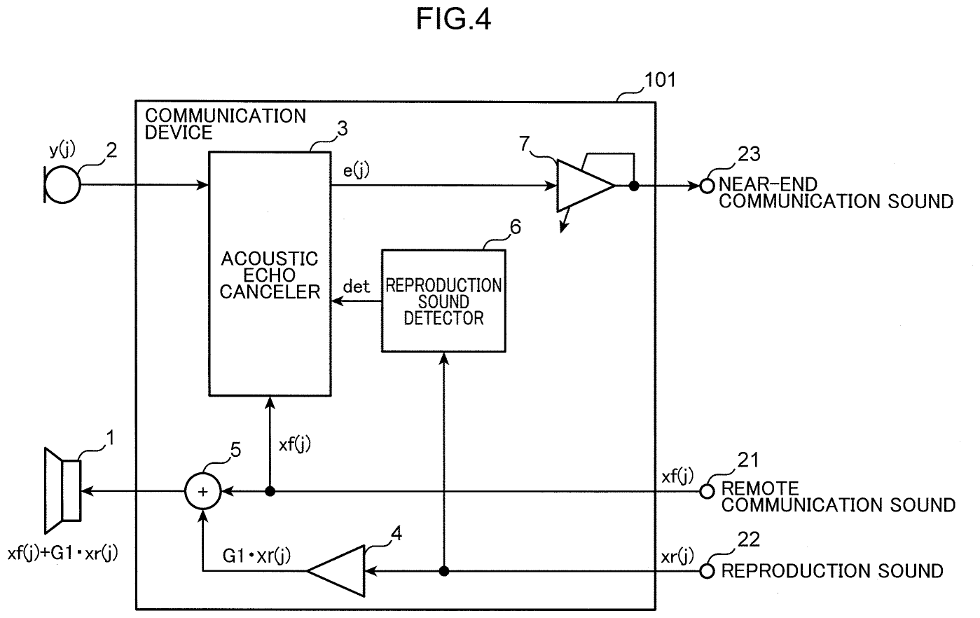

FIG. 4 is a diagram showing a configuration of a communication system in the second embodiment of the present disclosure.

The communication system shown in FIG. 4 includes a speaker 1, a microphone 2, a communication sound input part 21, a reproduction sound input part 22, a communication sound output part 23, and a communication device 101. In the second embodiment, elements which are the same as those in the first embodiment are given the same reference signs and numerals, and thus, descriptions therefor will be omitted.

The communication device 101 includes the acoustic echo canceler 3, a first amplifier 4, a first adder 5, a reproduction sound detector 6, and an automatic gain controller 7. The communication device 101 shown in FIG. 4 additionally includes the automatic gain controller 7 between the acoustic echo canceler 3 and the communication sound output part 23 in comparison with the communication device 100 shown in FIG. 1, and the remaining configuration is the same as the configuration shown in FIG. 1. The communication device 101 may include at least one of the speaker 1 and the microphone 2.

The acoustic echo canceler 3 outputs an echo removal signal to the automatic gain controller 7.

The automatic gain controller 7 automatically adjusts a sound volume indicated by an output signal from the acoustic echo canceler 3. The automatic gain controller 7 automatically adjusts a gain so that a level of a signal having been input to fall within a predetermined range. When a sound volume indicated by the input signal exceeds the predetermined range, the automatic gain controller 7 reduces an amplitude of the input signal in such a manner that a sound volume of an echo of a reproduction sound and a sound volume of an uttering sound of a near-end utterer agree with each other. This allows both the echo of the reproduction sound and the uttering sound of the near-end utterer to be easily audible at a remote location.

Subsequently, an operation by the communication device 101 according to the second embodiment of the disclosure will be described.

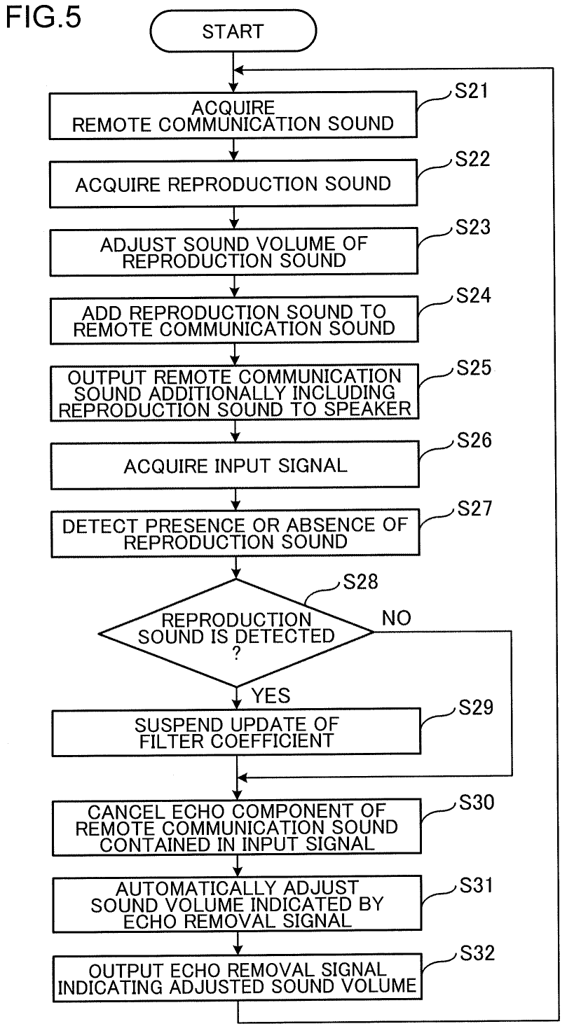

FIG. 5 is a flowchart explaining the operation by the communication device 101 according to the second embodiment of the disclosure.

Step S21 to step S30 in FIG. 5 are the same as step S1 to step S10 in FIG. 3, and thus, descriptions therefor will be omitted.

Next, in step S31, the automatic gain controller 7 automatically adjusts a sound volume indicated by an echo removal signal output from the acoustic echo canceler 3. The automatic gain controller 7 automatically adjusts a gain so that the sound volume indicated by the echo removal signal falls within a predetermined range.

Subsequently, in step S32, the automatic gain controller 7 outputs the echo removal signal indicating the adjusted sound volume. The automatic gain controller 7 outputs the echo removal signal indicating the adjusted sound volume to the communication sound output part 23. The communication sound output part 23 sends, to a remote supervising device (not shown) at a receiver, the echo removal signal output from the automatic gain controller 7 to serve as a near-end communication sound.

This configuration achieves automatic adjustment of the sound volume indicated by the output signal from the acoustic echo canceler 3. Conclusively, the configuration allows a sound volume of an echo of a reproduction sound and a sound volume of an uttering sound of a near-end utterer in the vicinity of the microphone 2 to agree with each other in such a manner that both the echo of the reproduction sound and the uttering sound of the near-end utterer are easily audible to the remote utterer.

In the second embodiment, the communication device 101 may exclude the reproduction sound detector 6. In the second embodiment, the communication device 101 may further exclude the first amplifier 4.

### Third Embodiment

The third embodiment aims at reducing a difference between a sound volume of an echo of a reproduction sound and a sound volume of an uttering sound of a near-end utterer at a remote location in the same manner as the second embodiment.

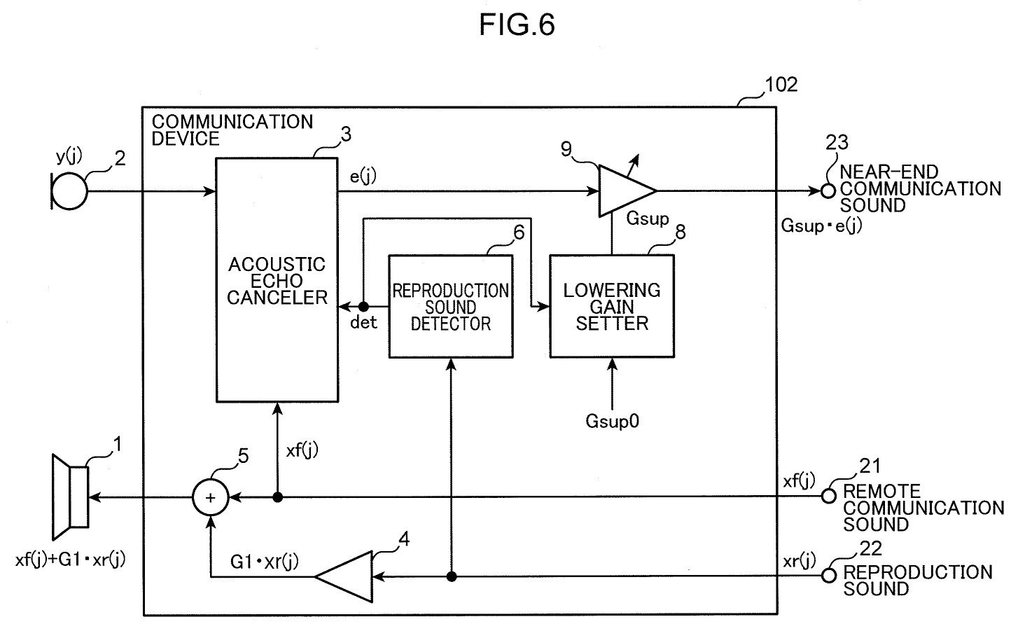

FIG. 6 is a diagram showing a configuration of a communication system in the third embodiment of the present disclosure.

The communication system shown in FIG. 6 includes a speaker 1, a microphone 2, a communication sound input part 21, a reproduction sound input part 22, a communication sound output part 23, and a communication device 102. In the third embodiment, elements which are the same as those in the first embodiment are given the same reference signs and numerals, and thus, descriptions therefor will be omitted.

The communication device 102 includes an acoustic echo canceler 3, a first amplifier 4, a first adder 5, a reproduction sound detector 6, a lowering gain setter 8, and a variable amplifier 9. The communication device 102 shown in FIG. 6 additionally includes the lowering gain setter 8 and the variable amplifier 9 in comparison with the communication device 100 shown in FIG. 1, and the remaining configuration is the same as the configuration shown in FIG. 1. The communication device 102 may include at least one of the speaker 1 and the microphone 2.

When the reproduction sound detector 6 detects a reproduction sound, the lowering gain setter 8 sets a first lowering gain for lowering a sound volume indicated by an output signal from the acoustic echo canceler 3. When the reproduction sound detector 6 does not detect the reproduction sound, the lowering gain setter 8 sets a second lowering gain for avoiding the lowering of the sound volume indicated by the output signal from the acoustic echo canceler 3.

When the reproduction sound detector 6 detects a reproduction sound, the lowering gain setter 8 sets a lowering gain Gsup(j) for the variable amplifier 9 to the first lowering gain Gsup0 for suppressing a signal. When the reproduction sound detector 6 does not detect the reproduction sound, the lowering gain setter 8 sets the lowering gain Gsup(j) for the variable amplifier 9 to the second lowering gain Gsup1 for avoiding the suppressing of the signal. The first lowering gain Gsup0 has a predetermined value to fall within a range “0<Gsup0<1”. The second lowering gain Gsup1 is “1”. The value of the first lowering gain Gsup0 is preset so that a sound volume of an echo of the reproduction sound which is audible at the remote location and a sound volume of the uttering sound of the near-end utterer are equal to each other.

The variable amplifier 9 multiplies an output signal from the acoustic echo canceler 3 by the first lowering gain or the second lowering gain set by the lowering gain setter 8.

Subsequently, an operation by the communication device 102 according to the third embodiment of the disclosure will be described.

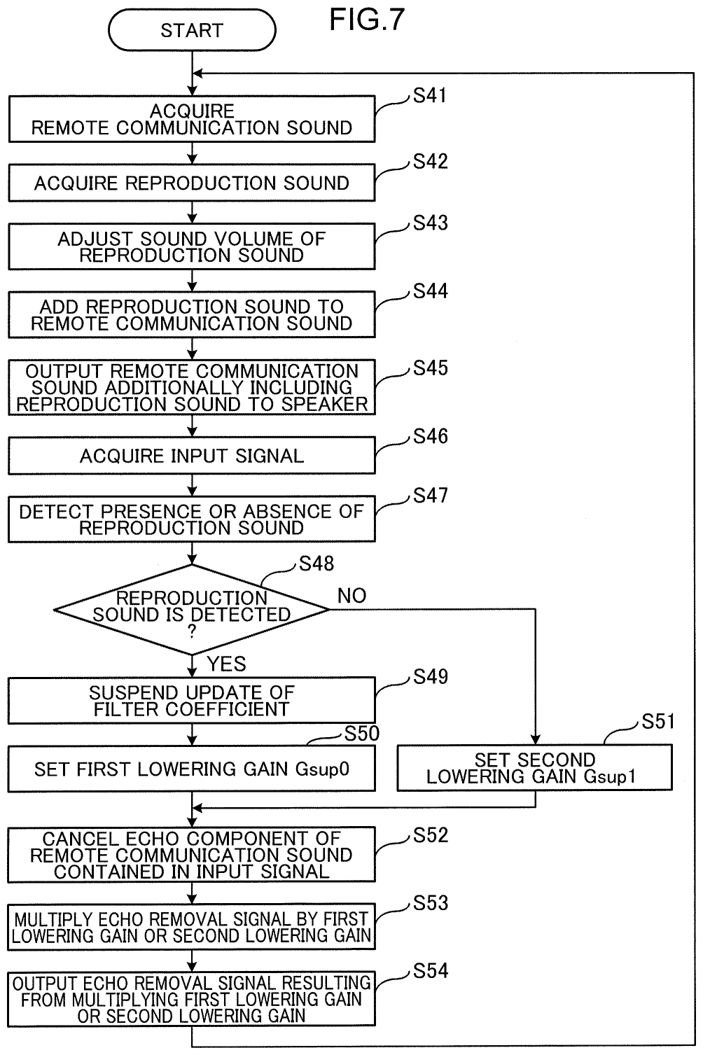

FIG. 7 is a flowchart explaining the operation by the communication device 102 according to the third embodiment of the disclosure.

Step S41 to step S49 in FIG. 7 are the same as step S1 to step S9 in FIG. 3, and thus, descriptions therefor will be omitted.

Next, in step S50, the lowering gain setter 8 sets the first lowering gain Gsup0 for lowering a sound volume indicated by an output signal from the acoustic echo canceler 3 for the variable amplifier 9.

When it is determined that a reproduction sound is not detected (NO in step S48), the lowering gain setter 8 sets the second lowering gain Gsup1 for avoiding the lowering of the sound volume indicated by the output signal from the acoustic echo canceler 3 for the variable amplifier 9 in step S51. The second lowering gain Gsup1 is “1”.

Step S52 in FIG. 7 is the same as step S10 in FIG. 3, and thus, descriptions therefor will be omitted.

Next, in step S53, the variable amplifier 9 multiplies an echo removal signal output from the acoustic echo canceler 3 by the first lowering gain or the second lowering gain set by the lowering gain setter 8.

Subsequently, in step S54, the variable amplifier 9 outputs the echo removal signal resulting from multiplying the first lowering gain or the second lowering gain. The variable amplifier 9 outputs the echo removal signal to the communication sound output part 23. The communication sound output part 23 sends, to a remote supervising device (not shown) at a receiver, the echo removal signal output from the variable amplifier 9 to serve as a near-end communication sound.

Conclusively, this configuration includes setting the first lowering gain to be multiplied by an output signal from the acoustic echo canceler 3 so that a sound volume of an echo of a reproduction sound which is audible to a remote utterer and a sound volume of an uttering sound of a near-end utterer are equal to each other when the reproduction sound is detected. Consequently, the configuration allows the sound volume of the echo of the reproduction sound and the sound volume of the uttering sound of the near-end utterer in a vicinity of the microphone 2 to agree with each other in such a manner that both the echo of the reproduction sound and the uttering sound of the near-end utterer are easily audible to the remote utterer.

In the third embodiment, the communication device 102 may exclude the first amplifier 4.

### Fourth Embodiment

The fourth embodiment aims at reducing a difference between a sound volume of an echo of a reproduction sound and a sound volume of an uttering sound of a near-end utterer at a remote location in the same manner as the second embodiment.

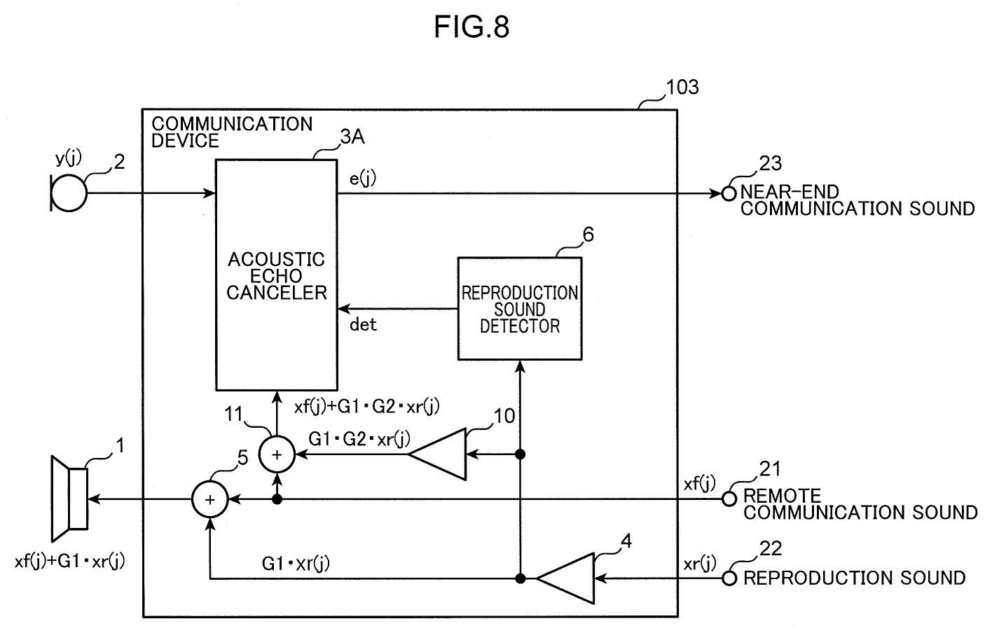

FIG. 8 is a diagram showing a configuration of a communication system in the fourth embodiment of the present disclosure.

The communication system shown in FIG. 8 includes a speaker 1, a microphone 2, a communication sound input part 21, a reproduction sound input part 22, a communication sound output part 23, and a communication device 103. In the fourth embodiment, elements which are the same as those in the first embodiment are given the same reference signs and numerals, and thus, descriptions therefor will be omitted.

The communication device 103 includes an acoustic echo canceler 3A, a first amplifier 4, a first adder 5, a reproduction sound detector 6, a second amplifier 10, and a second adder 11. The communication device 103 shown in FIG. 8 additionally includes the second amplifier 10 and the second adder 11 in comparison with the communication device 100 shown in FIG. 1, and the remaining configuration is the same as the configuration shown in FIG. 1. The communication device 103 may include at least one of the speaker 1 and the microphone 2.

The second amplifier 10 lowers a sound volume of a reproduction sound. The second amplifier 10 serves as an example sound volume lowering part. The second amplifier 10 multiplies an output signal G1·xr(j) from the first amplifier 4 by a predetermined gain G2 (0<G2<1). The second amplifier 10 controls an amplitude of the output signal from the first amplifier 4.

The second adder 11 adds the reproduction sound having the sound volume lowered by the second amplifier 10 to a remote communication sound. The second adder 11 adds an output signal G1·G2·xr(j) from the second amplifier 10 to a remote communication sound xf(j). The second adder 11 generates a reference signal xf(j)+G1·G2·xr(j) for the acoustic echo canceler 3A.

The acoustic echo canceler 3A cancels, on the basis of an output signal from the second adder 11 to be a reference signal, an echo component of each of the remote communication sound and the reproduction sound having the lowered sound volume contained in an input signal acquired by the microphone 2.

The second adder 11 adds the output signal G1·G2·xr(j) from the second amplifier 10 to the remote communication sound xf(j) when the reproduction sound xf(j) is reproduced in a state where an echo of the remote communication sound xf(j) is removed in progress of an update of a filter coefficient HHAT(j) of the acoustic echo canceler 3A and accurate deduction of an impulse response H in an acoustic echo route from the speaker 1 to the microphone 2.

An input signal y(j) output from the microphone 2 is expressed with the aforementioned Equation (2) including an input signal series Xf(j)+G1·Xr(j) of the speaker 1 and an impulse response H in an acoustic echo route from the speaker 1 to the microphone 2.

The acoustic echo canceler 3A generates a deduced echo yhat(j) through convolution of the deduced filter coefficient HHAT(j) on the output signal series Xf(j)+G1·G2·Xr(j) of the second adder 11 as expressed with the following Equation (13).

$$yhat ( j ) = HHAT ( j ) * ( Xf ( j ) + G 1 \cdot G 2 \cdot Xr ( j ) ) \qquad ( 13 )$$

The echo removal signal e(j) output from the acoustic echo canceler 3A is expressed with the following Equation (14).

$$\begin{matrix}e ( j ) = y ( j ) - yhat ( j ) \\ = H * ( Xf ( j ) + G 1 \cdot Xr ( j ) ) - HHAT ( j ) * ( Xf ( j ) + G 1 \cdot G 2 \cdot Xr ( j ) \\ = ( H - HHAT ( j ) ) * ( Xf ( j ) + G 1 \cdot Xr ( j ) ) + G 1 \cdot ( 1 - G 2 ) \cdot HHAT ( j ) * Xr ( j )\end{matrix} \qquad ( 14 )$$

The echo removal signal e(j) output from the acoustic echo canceler 3A in the case of HHAT(j)=H in Equation (14) is expressed with the following Equation (15).

$$e ( j ) = G 1 \cdot ( 1 - G 2 ) \cdot H * Xr ( j ) \qquad ( 15 )$$

As shown in Equation (14) and Equation (15), the echo by “G1·G2” of each of the remote communication sound xf(j) and the reproduction sound xr(j) is removed by the acoustic echo canceler 3A, but the echo component G1·(1−G2)·H*Xr(j) by “G1·(1−G2)” is output from the acoustic echo canceler 3A without being removed.

In presence of a reproduction sound, a signal for loud producing from the speaker 1 indicates “xf(j)+G1·xr(j)”, and a reference signal indicates “xf(j)+G1·G2·xr(j)”. The signal in the loud producing from the speaker 1 differs from the reference signal. Updating the filter coefficient HHAT(j) in this situation results in an incorrect update. To avoid the incorrect update, when the reproduction sound detector 6 detects the reproduction sound xr(j), the acoustic echo canceler 3A suspends the update of the filter coefficient HHAT(j) in the same manner as in the first embodiment. In contrast, when the reproduction sound xr(j) is not detected, the acoustic echo canceler 3A updates the filter coefficient.

Adjustment of the gain G2 for the second amplifier 10 leads to achievement in the control of the sound volume of the echo component G1·(1−G2)·H*Xr(j) of the reproduction sound contained in the echo removal signal e(j) output from the acoustic echo canceler 3A to be equivalent to the sound volume of the uttering sound of the near-end utterer. This results in allowing both the uttering sound of the near-end utterer and the reproduction sound to be easily audible to the remote supervising device.

Subsequently, an operation by the communication device 103 according to the fourth embodiment of the disclosure will be described.

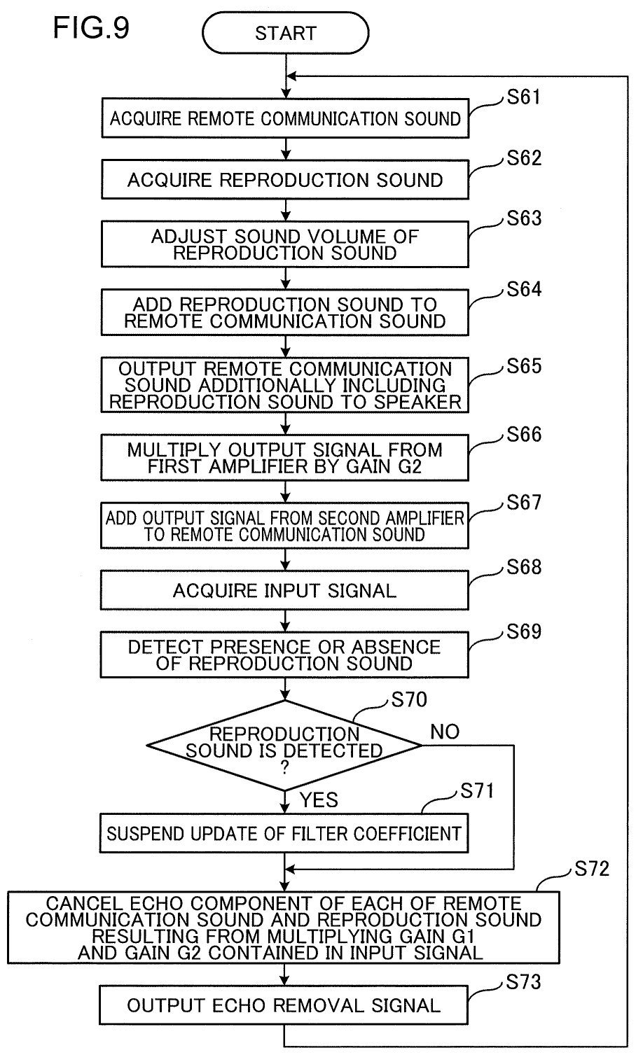

FIG. 9 is a flowchart explaining the operation by the communication device 103 according to the fourth embodiment of the disclosure.

Step S61 to step S65 in FIG. 9 are the same as step S1 to step S5 in FIG. 3, and thus, descriptions therefor will be omitted.

Next, in step S66, the second amplifier 10 multiplies an output signal (G1·xr(j)) from the first amplifier 4 by a predetermined gain G2. The second amplifier 10 outputs a reproduction sound (G1·G2·xr(j)) resulting from multiplying the gains G1 and G2 to the second adder 11.

Then, in step S67, the second adder 11 adds an output signal from the second amplifier 10 to a remote communication sound. The second adder 11 outputs, to the acoustic echo canceler 3A, the remote communication sound ((xf(j)+G1·G2·xr(j)), to which an output signal from the second amplifier 10 is added, to serve as a reference signal.

Step S68 to step S71 in FIG. 9 are the same as step S6 to step S9 in FIG. 3, and thus, descriptions therefor will be omitted.

Next, in step S72, the acoustic echo canceler 3A cancels, on the basis of the remote communication sound additionally including the reproduction sound having a lowered sound volume with the gains G1 and G2 to serve as a reference signal, an echo component of each of the remote communication sound and the reproduction sound resulting from multiplying the gains G1 and G2 contained in an input signal acquired by the microphone 2.

Subsequently, in step S73, the acoustic echo canceler 3A outputs an echo removal signal excluding, from the input signal, the echo component of each of the remote communication sound and the reproduction sound resulting from multiplying the gains G1 and G2. The acoustic echo canceler 3A outputs the echo removal signal to the communication sound output part 23. The communication sound output part 23 sends, to a remote supervising device (not shown) at a receiver, the echo removal signal output from the acoustic echo canceler 3A to serve as a near-end communication sound.

Conclusively, a sound volume of the reproduction sound output from the speaker 1 differs from a sound volume of the reproduction sound input into the acoustic echo canceler 3A to serve as a reference signal. Hence, an echo component in a part of the reproduction sound is output without being canceled by the acoustic echo canceler 3A. The configuration accordingly enables the remote utterer to confirm whether the reproduction sound is loudly produced.

In the second embodiment and the third embodiment, a lowering gain changes depending on presence or absence of a reproduction sound. Such a change in the lowering gain may cause a fluctuation in a background noise in the second embodiment and the third embodiment. Further, in a case where a reproduction sound is reproduced concurrently with inputting of an uttering sound of a near-end utterer, the change in the lowering gain may lead to lowering of the uttering sound of the near-end utterer in the second embodiment and the third embodiment. In contrast, in such case where a reproduction sound is reproduced concurrently with inputting of an uttering sound of a near-end utterer, the fourth embodiment has an advantage of avoiding the lowering of the uttering sound of the near-end utterer without suppression of an output from the acoustic echo canceler 3A and a fluctuation in a background noise.

### Fifth Embodiment

The fourth embodiment achieves appropriate control of a sound volume of a reproduction sound included in an output from the acoustic echo canceler 3A in a state where the acoustic echo canceler 3A satisfactorily removes an echo. In contrast, the fifth embodiment aims at appropriately controlling a sound volume of a reproduction sound included in an output from an acoustic echo canceler 3A even in a state where the acoustic echo canceler 3A does not satisfactorily remove an echo.

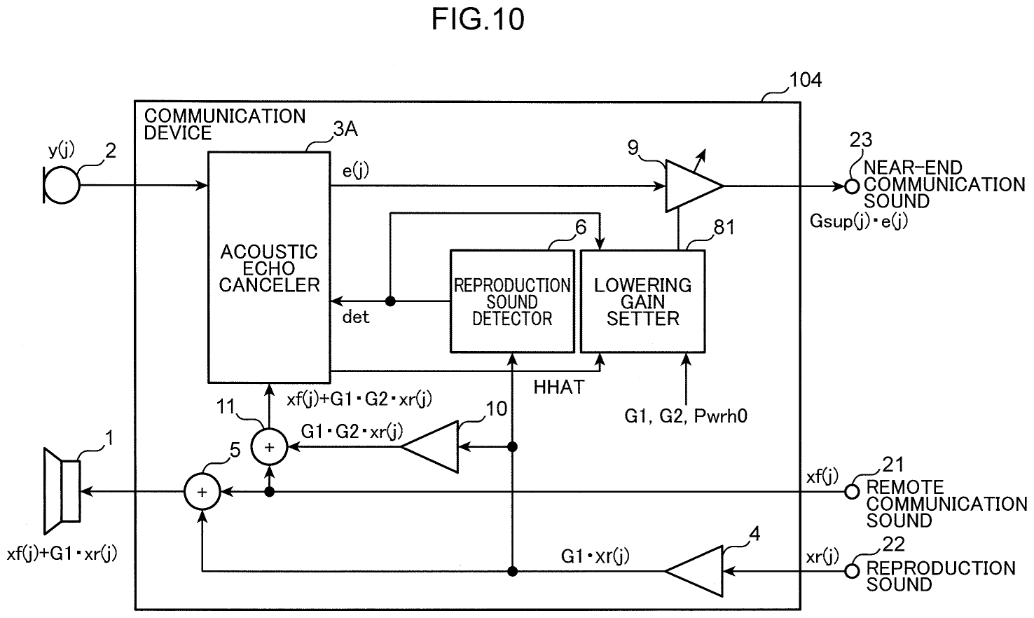

FIG. 10 is a diagram showing a configuration of a communication system in the fifth embodiment of the present disclosure.

The communication system shown in FIG. 10 includes a speaker 1, a microphone 2, a communication sound input part 21, a reproduction sound input part 22, a communication sound output part 23, and a communication device 104. In the fifth embodiment, elements which are the same as those in the first to fourth embodiments are given the same reference signs and numerals, and thus, descriptions therefor will be omitted.

The communication device 104 includes the acoustic echo canceler 3A, a first amplifier 4, a first adder 5, a reproduction sound detector 6, a variable amplifier 9, a second amplifier 10, a second adder 11, and a lowering gain setter 81. The communication device 104 shown in FIG. 10 additionally includes the lowering gain setter 81 and the variable amplifier 9 in comparison with the communication device 103 shown in FIG. 8, and the remaining configuration is the same as the configuration shown in FIG. 8. The communication device 104 may include at least one of the speaker 1 and the microphone 2.

When the reproduction sound detector 6 detects a reproduction sound, the lowering gain setter 81 estimates an echo cancelation amount of the acoustic echo canceler 3A. The lowering gain setter 81 calculates a power value of a filter coefficient and estimates the echo cancelation amount from the calculated power value of the filter coefficient. The lowering gain setter 81 calculates a first lowering gain for lowering a sound volume indicated by an output signal from the acoustic echo canceler 3A in association with the estimated echo cancelation amount, and sets the calculated first lowering gain.

When the reproduction sound detector 6 does not detect the reproduction sound, the lowering gain setter 81 sets a second lowering gain for avoiding the lowering of the sound volume indicated by the output signal from the acoustic echo canceler 3A.

The variable amplifier 9 multiplies the output signal from the acoustic echo canceler 3A by the first lowering gain or the second lowering gain set by the lowering gain setter 81.

When the reproduction sound detector 6 detects a reproduction sound, the lowering gain setter 81 calculates an estimated value (∥HHAT(j)∥)^{1/2}/Pwrh0 of the echo cancelation amount of the acoustic echo canceler 3A by utilizing a filter coefficient HHAT(j) of the acoustic echo canceler 3A. The sign “∥HHAT(j)∥” denotes a norm of the coefficient “HHAT(j)” and is expressed with the following Equation (16). The sign “Pwrh0” denotes a square route of a total power value of impulse responses in an acoustic echo route ((∥H∥)^{1/2}). The lowering gain setter 81 then sets a lowering gain Gsup(j) for the variable amplifier 9 to a first lowering gain Gsup0 on the basis of the estimated value of the echo cancelation amount.

$$‖ HHAT ( j ) ‖ = {hhat ( j , 0 )}^{2} + {hhat ( j , 1 )}^{2} + … + {hhat ( j , N - 1 )}^{2} \qquad ( 16 )$$

When the reproduction sound detector 6 does not detect a reproduction sound, the lowering gain setter 81 sets the lowering gain Gsup(j) for the variable amplifier 9 to the second lowering gain Gsup1 for avoiding suppressing of a signal. The second lowering gain Gsup1 is “1”.

The variable amplifier 9 suppresses the output signal from the acoustic echo canceler 3A with the first lowering gain Gsup0 or the second lowering gain Gsup1 set by the lowering gain setter 81.

Specifically, when the reproduction sound detector 6 detects a reproduction sound, the lowering gain setter 81 sets the first lowering gain Gsup0 in accordance with the following Equation (17).

$$Gsup 0 = min ( ( 1 - G 2 ) / ( 1 - G 2 \cdot ( {‖ HHAT ( j ) ‖}^{1 / 2} / Pwrh 0 ) , 1 ) \qquad ( 17 )$$

In Equation (17), the sign “min(a, b)” means selection of a smaller value from “a” and “b”. The sign “G1” denotes a gain (0<G1) for the first amplifier 4, the sign “G2” denotes a gain (0<G2≤1) for the second amplifier 10, and the sign “j” denotes a time.

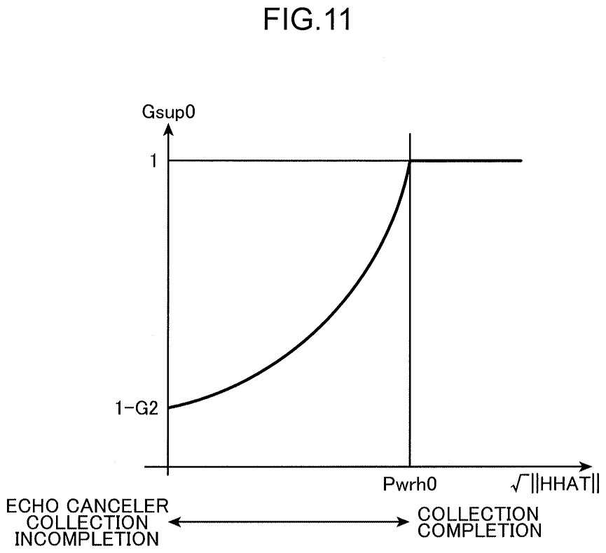

FIG. 11 is a graph showing a relation between a power value of a filter coefficient and a first lowering gain when a reproduction sound is detected in the fifth embodiment.

The first lowering gain Gsup0 approaches “1” as the norm ∥HHAT(j)∥ gradually increases in progress of an update of the filter coefficient HHAT(j) of the acoustic echo canceler 3A. In contrast, in a state of no update of the filter coefficient HHAT(j) by the acoustic echo canceler 3A, that is, in the case of “∥HHAT(j)∥=0”, the first lowering gain Gsup0 reaches “1−G2” and the echo component of the reproduction sound is suppressed or lowered in the variable amplifier 9. In this case, a sound volume of an echo of the reproduction sound at a remote location is equal to a sound volume of an echo of the reproduction sound resulting from satisfactorily removing the echo by the acoustic echo canceler 3A. When the acoustic echo canceler 3A satisfactorily cancels the echo, the first lowering gain Gsup0 reaches “1”. The result is the same as the result in the fourth embodiment. The fifth embodiment enables control of a lowering gain for a reproduction sound depending on a situation of removal of an echo by the acoustic echo canceler 3A, and thus allows a sound volume of the reproduction sound and a sound volume of an uttering sound of a near-end utterer at the remote location to be equal to each other without relying on an echo cancelation amount of the acoustic echo canceler 3A.

Subsequently, an operation by the communication device 104 according to the fifth embodiment of the disclosure will be described.

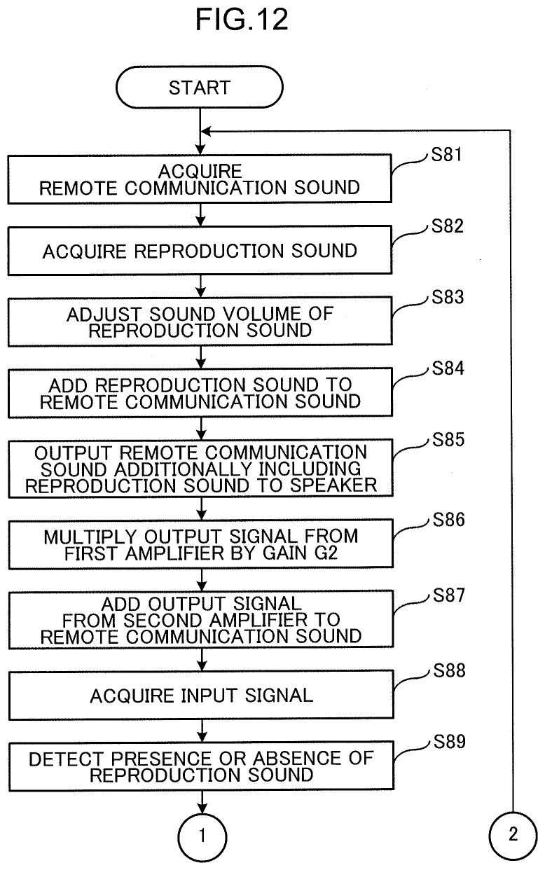

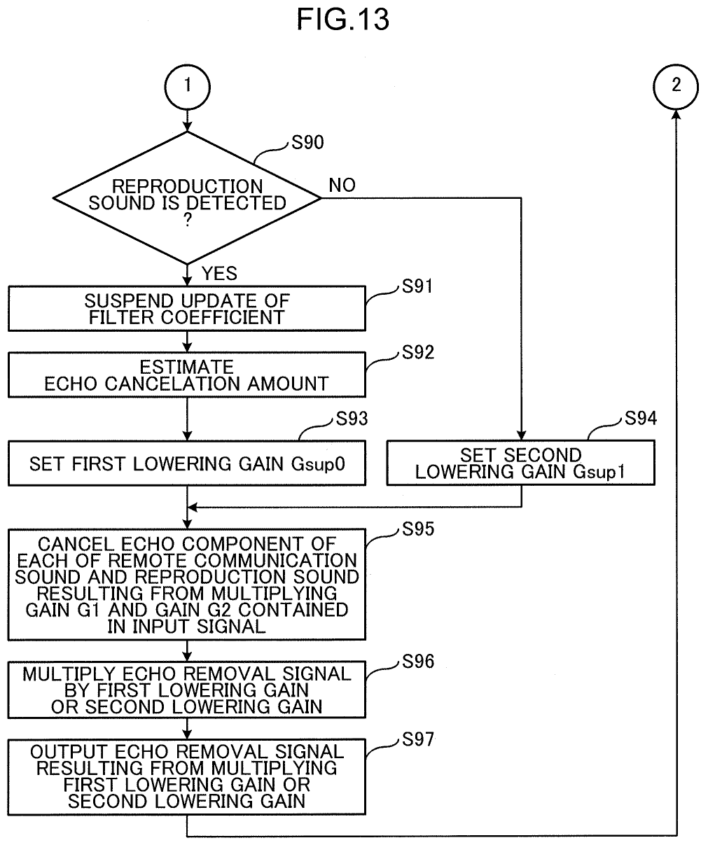

FIG. 12 is a first flowchart explaining the operation by the communication device 104 according to the fifth embodiment of the disclosure. FIG. 13 is a second flowchart explaining the operation by the communication device 104 according to the fifth embodiment of the disclosure.

Step S81 to step S91 in FIG. 12 and FIG. 13 are the same as step S61 to step S71 in FIG. 9, and thus, descriptions therefor will be omitted.

Next, in step S92, the lowering gain setter 81 calculates a power value of a filter coefficient of the acoustic echo canceler 3A and estimates an echo cancelation amount of the acoustic echo canceler 3A from the calculated power value of the filter coefficient.

Subsequently, in step S93, the lowering gain setter 81 calculates the first lowering gain Gsu0 for lowering a sound volume indicated by an output signal from the acoustic echo canceler 3A in association with the estimated echo cancelation amount, and sets the calculated first lowering gain Gsup0 for the variable amplifier 9.

When it is determined that a reproduction sound is not detected (NO in step S90), the lowering gain setter 81 sets the second lowering gain Gsup 1 for avoiding the lowering of the sound volume indicated by the output signal from the acoustic echo canceler 3A for the variable amplifier 9 in step S94. The second lowering gain Gsup1 is “1”.

Step S95 in FIG. 13 is the same as step S72 in FIG. 9, and thus, descriptions therefor will be omitted. Step S96 and step S97 in FIG. 13 are the same as step S53 to step S54 in FIG. 7, and thus, descriptions therefor will be omitted.

Conclusively, this configuration includes setting the first lowering gain to be multiplied by an output signal from the acoustic echo canceler 3A, depending on a situation of removal of an echo by the acoustic echo canceler 3A, so that a sound volume of the echo of the reproduction sound and a sound volume of an uttering sound of a near-end utterer which are audible to a remote utterer are equal to each other when the reproduction sound is detected. Consequently, the configuration allows the sound volume of the echo of the reproduction sound and the sound volume of the uttering sound of the near-end utterer in the vicinity of the microphone 2 to agree with each other in such a manner that both the echo of the reproduction sound and the uttering sound of the near-end utterer are easily audible to the remote utterer.

Besides, when the filter coefficient is not updated and the filter coefficient has a small power value, the echo cancelation amount reduces and the sound volume of the echo of the reproduction sound output from the acoustic echo canceler 3A increases. Hence, the echo component of the reproduction sound is suppressed or lowered with the first lowering gain until the power value of the filter coefficient increases in progress of the update of the filter coefficient. Consequently, the configuration allows the sound volume of the echo of the reproduction sound and the sound volume of the uttering sound of the near-end utterer in the vicinity of the microphone 2 to agree with each other in such a manner that both the echo of the reproduction sound and the uttering sound of the near-end utterer are easily audible to the remote utterer.

### Sixth Embodiment

The lowering gain setter 81 in the fifth embodiment estimates an echo cancelation amount from a power value of a filter coefficient of the acoustic echo canceler 3A. In contrast, a lowering gain setter in the sixth embodiment estimates an echo cancelation amount on the basis of a level of an input signal input into an acoustic echo canceler 3A from a microphone 2 and a level of an output signal from the acoustic echo canceler 3A.

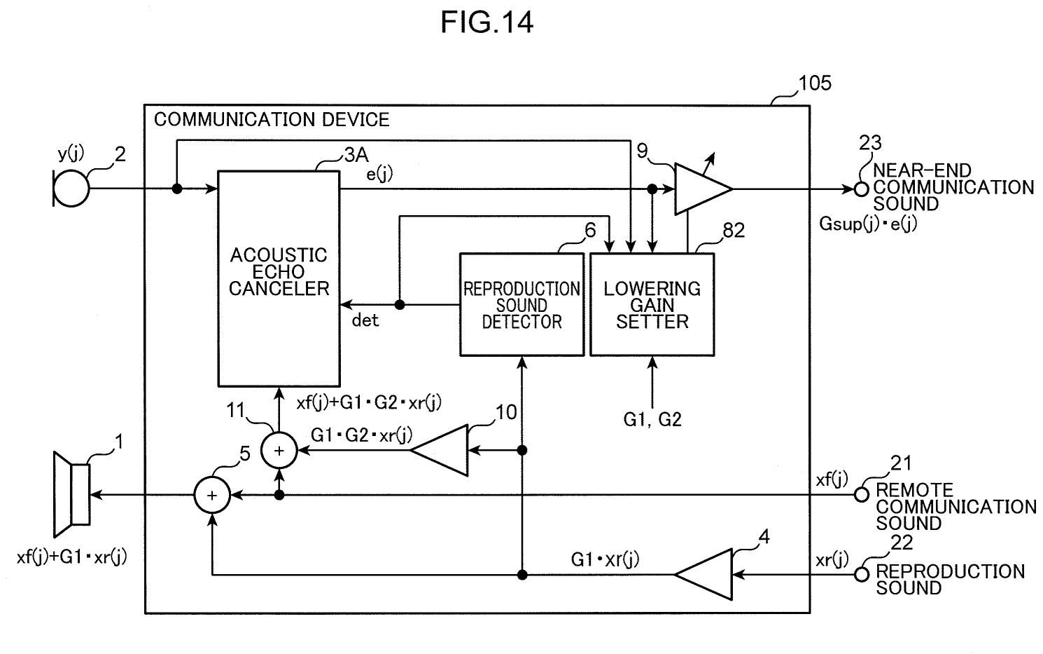

FIG. 14 is a diagram showing a configuration of a communication system in the sixth embodiment of the present disclosure.

The communication system shown in FIG. 14 includes a speaker 1, the microphone 2, a communication sound input part 21, a reproduction sound input part 22, a communication sound output part 23, and a communication device 105. In the sixth embodiment, elements which are the same as those in the first to fifth embodiments are given the same reference signs and numerals, and thus, descriptions therefor will be omitted.

The communication device 105 includes the acoustic echo canceler 3A, a first amplifier 4, a first adder 5, a reproduction sound detector 6, a variable amplifier 9, a second amplifier 10, a second adder 11, and a lowering gain setter 82. The communication device 105 shown in FIG. 14 includes the lowering gain setter 82 in place of the lowering gain setter 81 of the communication device 104 shown in FIG. 10, and the remaining configuration is the same as the configuration shown in FIG. 10. The communication device 105 may include at least one of the speaker 1 and the microphone 2.

When the reproduction sound detector 6 detects a reproduction sound, the lowering gain setter 82 estimates an echo cancelation amount of the acoustic echo canceler 3A. The lowering gain setter 82 estimates the echo cancelation amount on the basis of a level of an input signal input into the acoustic echo canceler 3A from the microphone 2 and a level of an output signal from the acoustic echo canceler 3A. The lowering gain setter 82 calculates a first lowering gain for lowering a sound volume indicated by the output signal from the acoustic echo canceler 3A in association with the estimated echo cancelation amount, and sets the calculated first lowering gain.

When the reproduction sound detector 6 does not detect the reproduction sound, the lowering gain setter 82 sets a second lowering gain for avoiding the lowering of the sound volume indicated by the output signal from the acoustic echo canceler 3A.

When the reproduction sound detector 6 does not detect a reproduction sound, the lowering gain setter 82 estimates an echo cancelation amount can(j) from a ratio between a level of an input signal into the acoustic echo canceler 3A and a level of an output signal from the acoustic echo canceler 3A. When the reproduction sound detector 6 does not detect the reproduction sound, the lowering gain setter 82 calculates the echo cancelation amount can(j) in accordance with the following Equation (18).

$$can ( j ) = min ( {e}^{\sim} ( j ) / {y}^{\sim} ( j ) , 1 ) \qquad ( 18 )$$

In Equation (18), the sign “e(j)” denotes a short-time average value of absolute values of the echo removal signal e(j), the sign “y(j)” denotes a short-time average value of absolute values of an input signal y(j), and the sign “min(a, b)” means selection of a smaller value from “a” and “b”, and the sign “j” denotes a time. The short-time average value y(j) of the input signal y(j) and the short-time average value e(j) of the output signal e(j) concerning the acoustic echo canceler 3A are calculated in the same manner as the level xr(j) in Equation (1).

When the reproduction sound detector 6 detects a reproduction sound, the lowering gain setter 82 holds a previously estimated echo cancelation amount. When the reproduction sound detector 6 detects the reproduction sound, the lowering gain setter 82 calculates the echo cancelation amount can(j) in accordance with the following Equation (19).

$$can ( j ) = can ( j - 1 ) \qquad ( 19 )$$

When the reproduction sound detector 6 detects a reproduction sound, the lowering gain setter 82 calculates the first lowering gain Gsup0 in accordance with the following Equation (20), and sets a lowering gain Gsup(j) for the variable amplifier 9 to the calculated first lowering gain Gsup0.

$$Gsup 0 = ( 1 - G 2 ) / ( 1 - G 2 + G 2 \cdot can ( j ) ) \qquad ( 20 )$$

In Equation (20), the sign “G1” denotes a gain (0<G1) for the first amplifier 4, the sign “G2” denotes a gain (0<G2≤1) for the second amplifier 10, and the sign “j” denotes a time.

When the reproduction sound detector 6 does not detect the reproduction sound, the lowering gain setter 82 sets the lowering gain Gsup(j) for the variable amplifier 9 to the second lowering gain Gsup1 for avoiding suppressing of a signal. The second lowering gain Gsup1 is “1”.

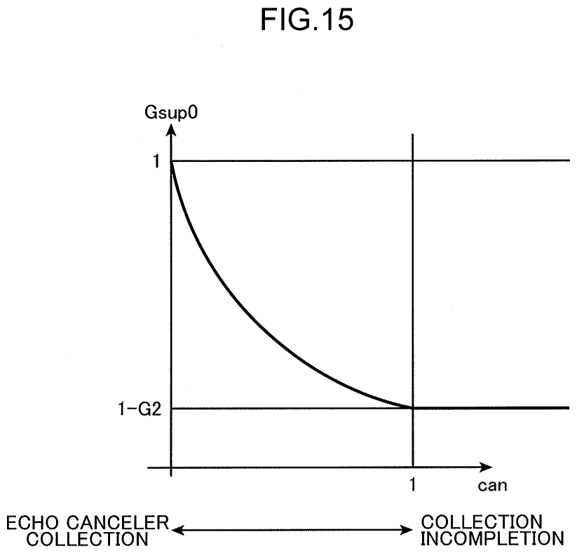

FIG. 15 is a graph showing a relation between an echo cancelation amount and a first lowering gain when a reproduction sound is detected in the sixth embodiment.

When the reproduction sound detector 6 does not detect the reproduction sound, suppression or lowering of an echo is not executed. Hence, the lowering gain Gsup(j) for the variable amplifier 9 is “1”, that is, a second lowering gain Gsup1.

When the reproduction sound detector 6 detects a reproduction sound and the acoustic echo canceler 3A does not cancel an echo at all, the echo cancelation amount can(j) reaches “1” and the first lowering gain Gsup0 becomes minimum. At this time, the first lowering gain Gsup0 reaches “1−G2”.

In contrast, when the reproduction sound detector 6 detects a reproduction sound and the acoustic echo canceler 3A satisfactorily cancels the echo, the echo cancelation amount can (j) reduces. In a case of “can(j)≈0”, the first lowering gain Gsup0 reaches “1”.

The process in the sixth embodiment is the same as the process in the fifth embodiment except for calculation of a lowering gain that is different from the calculation in the fifth embodiment. From this perspective, description about the operation of the communication device 105 in the sixth embodiment will be omitted.

In the sixth embodiment, the echo cancelation amount shows, for example, a ratio between a level of an input signal input into the acoustic echo canceler 3A from the microphone 2 and a level of an output signal from the acoustic echo canceler 3A. When the acoustic echo canceler 3A does not cancel the echo, the echo cancelation amount reaches “1” and the sound volume of the echo of the reproduction sound output from the acoustic echo canceler 3A increases. Hence, the echo component of the reproduction sound is suppressed or lowered with the first lowering gain until the acoustic echo canceler 3A satisfactorily cancels the echo. Consequently, the configuration allows the sound volume of the echo of the reproduction sound and a sound volume of an uttering sound of a near-end utterer in the vicinity of the microphone 2 to agree with each other in such a manner that both the echo of the reproduction sound and the uttering sound of the near-end utterer are easily audible to a remote utterer.

### Seventh Embodiment

In the first embodiment, only a remote communication sound is input into the acoustic echo canceler 3 to serve as a reference signal. In contrast, in the seventh embodiment, a remote communication sound additionally including a reproduction sound is input into an acoustic echo canceler to serve as a reference signal, and furthermore, the reproduction sound is added to an output signal from the acoustic echo canceler.

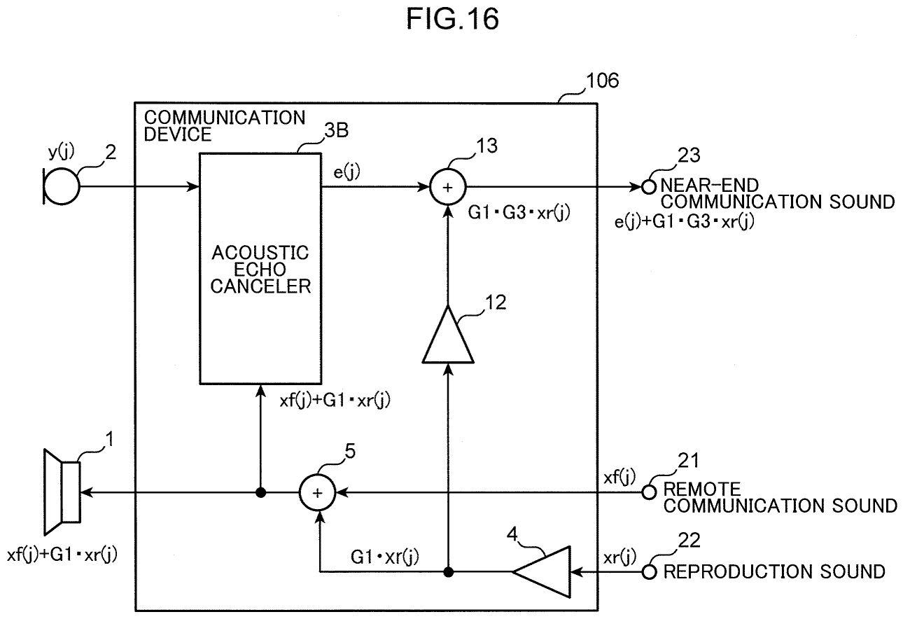

FIG. 16 is a diagram showing a configuration of a communication system in the seventh embodiment of the present disclosure.

The communication system shown in FIG. 16 includes a speaker 1, a microphone 2, a communication sound input part 21, a reproduction sound input part 22, a communication sound output part 23, and a communication device 106. In the seventh embodiment, elements which are the same as those in the first embodiment are given the same reference signs and numerals, and thus, descriptions therefor will be omitted.

The communication device 106 includes an acoustic echo canceler 3B, a first amplifier 4, a first adder 5, a third amplifier 12, and a third adder 13. The communication device 106 may include at least one of the speaker 1 and the microphone 2.

The first adder 5 adds a remote communication sound and an output signal G1·xr(j) from the first amplifier. The first adder 5 adds a reproduction sound to the remote communication sound of a remote utterer, and outputs the communication sound additionally including the reproduction sound to each of the speaker 1 and the acoustic echo canceler 3B. An output signal xf(j)+G1·xr(j) from the first adder 5 serves as a reference signal for the acoustic echo canceler 3B. The output signal from the first adder 5 is in loud producing from the speaker 1 as well.

The acoustic echo canceler 3B cancels, on the basis of the output signal from the first adder 5 to be the reference signal, an echo component of each of the communication sound and the reproduction sound contained in an input signal acquired by the microphone 2. The acoustic echo canceler 3B removes an echo component of the reproduction sound as well as an echo component of the remote communication sound. The acoustic echo canceler 3B receives a remote communication sound xf(j), which additionally includes the reproduction sound G1·xr(j) having an adjusted sound volume, to serve as the reference signal, and receives an input signal y(j) from the microphone 2. The acoustic echo canceler 3B removes an acoustic echo loudly produced from the speaker 1 and coming to the microphone 2.

The third amplifier 12 multiplies the reproduction sound by a predetermined gain G3. The third amplifier 12 adjusts a sound volume of the reproduction sound and outputs the reproduction sound having the adjusted sound volume to the third adder 13. The third amplifier 12 serves as an example second sound volume adjuster. The gain G3 for the third amplifier 12 is defined so that an uttering sound of a near-end utterer and a reproduction sound become equivalent to each other at a remote location.

The third adder 13 adds an output signal from the third amplifier 12 and an output signal from the acoustic echo canceler 3B. The third adder 13 adds the reproduction sound to the output signal from the acoustic echo canceler 3B. The third adder 13 serves as an example second adder. The third adder 13 adds the reproduction sound having the sound volume adjusted by the third amplifier 12 to the output signal from the acoustic echo canceler 3B.

The remote communication sound xf(j) is loudly produced from the speaker 1 and collected as an echo component by the microphone 2 in the same manner as in the first embodiment, but the echo component is removed by the acoustic echo canceler 3B. An echo component of the reproduction sound xr(j) is also removed by the acoustic echo canceler 3B unlike the corresponding echo component in the first embodiment.

The reproduction sound G1·G3·xr(j) having the sound volume adjusted by the third amplifier 12 is added to the echo removal signal e(j) output from the acoustic echo canceler 3B by the third adder 13, and a signal “e(j)+G1·G3·xr(j)” is sent to the remote location. This enables confirmation of the reproduction sound at the remote location.

In the first embodiment, an echo of a reproduction sound loudly produced from the speaker 1 and collected by the microphone 2 is sent to a remote location. In contrast, in the seventh embodiment, the reproduction sound G1·G3·xr(j) resulting from multiplying the reproduction sound G1·xr(j) input into the speaker 1 by the gain G3 for the third amplifier 12 is sent to the remote location. This provides an advantageous effect of successful confirmation of a clear reproduction sound without an acoustic echo at the remote location by avoiding passing through an acoustic echo route.

Subsequently, an operation by the communication device 106 according to the seventh embodiment of the disclosure will be described.

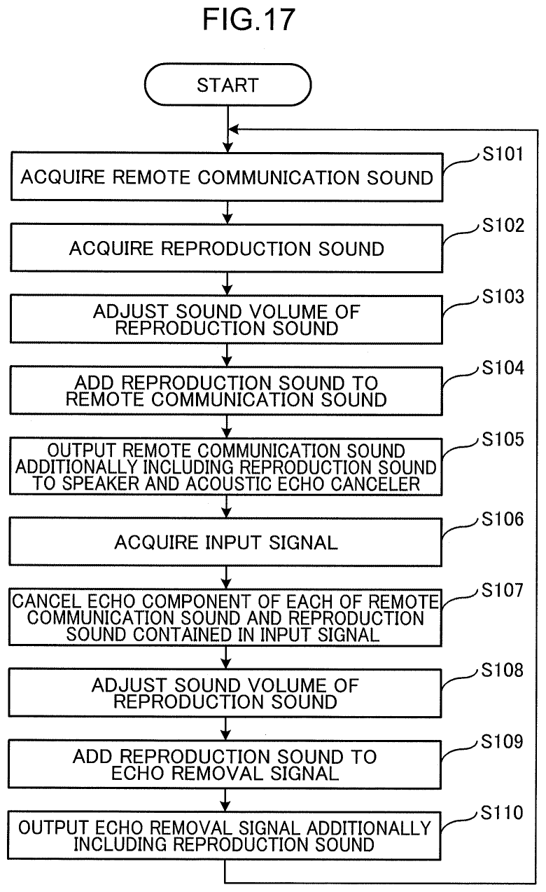

FIG. 17 is a flowchart explaining the operation by the communication device 106 according to the seventh embodiment of the disclosure.

Steps S101 to S102 in FIG. 17 are the same as steps S1 to S2 in FIG. 3, and thus, descriptions therefor will be omitted.

Next, in step S103, the first amplifier 4 adjusts a sound volume of a reproduction sound. The first amplifier 4 multiplies the reproduction sound by a predetermined gain G1. The gain G1 is determined in advance depending on an environment for use of the communication device 106. The first amplifier 4 outputs the reproduction sound having the adjusted sound volume to each of the first adder 5 and the third amplifier 12.

Step S104 in FIG. 17 is the same as step S4 in FIG. 3, and thus, descriptions therefor will be omitted.

Next, in step S105, the first adder 5 outputs a remote communication sound additionally including the reproduction sound to each of the speaker 1 and the acoustic echo canceler 3B. The speaker 1 loudly produces the remote communication sound additionally including the reproduction sound. The acoustic echo canceler 3B utilizes the remote communication sound additionally including the reproduction sound as a reference signal.

Step S106 in FIG. 17 is the same as step S6 in FIG. 3, and thus, descriptions therefor will be omitted.

Next, in step S107, the acoustic echo canceler 3B cancels, on the basis of the remote communication sound additionally including the reproduction sound to serve as the reference signal, an echo component of each of the remote communication sound and the reproduction sound contained in the input signal acquired by the microphone 2.

Subsequently, in step S108, the third amplifier 12 adjusts a sound volume of the reproduction sound resulting from multiplying the gain G1 output from the first amplifier 4. The third amplifier 12 multiplies an output signal from the first amplifier 4 by a predetermined gain G3. The gain G3 is determined in advance so that an uttering sound of a near-end utterer and the reproduction sound become equivalent to each other at a remote location. The third amplifier 12 outputs the reproduction sound having the adjusted sound volume to the third adder 13.

Then, in step S109, the third adder 13 adds the reproduction sound output from the third amplifier 12 to an echo removal signal output from the acoustic echo canceler 3B. The third adder 13 adds a reproduction sound G1·G3·xr(j) having the sound volume adjusted by the first amplifier 4 and the third amplifier 12 to an echo removal signal e(j) from the acoustic echo canceler 3B.

Thereafter, in step S110, the third adder 13 outputs the echo removal signal additionally including the reproduction sound to the communication sound output part 23. The communication sound output part 23 sends, to a remote supervising device (not shown) at a receiver, the echo removal signal output from the third adder 13 and additionally including the reproduction sound to serve as a near-end communication sound.

Conclusively, the acoustic echo canceler 3B removes the echo component of the reproduction sound coming from the speaker 1 to the microphone 2. Then, the reproduction sound is added to the output signal from the acoustic echo canceler 3B excluding the echo component of the reproduction sound, and an output signal additionally including the reproduction sound having not passed through an acoustic echo route is output toward a remote utterer. This enables the remote utterer to confirm a clear reproduction sound without an acoustic echo.

In the seventh embodiment, the communication device 106 may exclude the first amplifier 4 and the third amplifier 12.

### Eighth Embodiment

A remote utterer who plans to hold a remote meeting, a remote lecture, or other event has a demand for confirming that a communication sound of the remote utterer is loudly produced at a destination. Taking this into consideration, a communication device according to the eighth embodiment is configured to loudly produce a remote communication sound from a speaker 1 and return the remote communication sound collected by a microphone 2 to a remote communication device at a receiver.

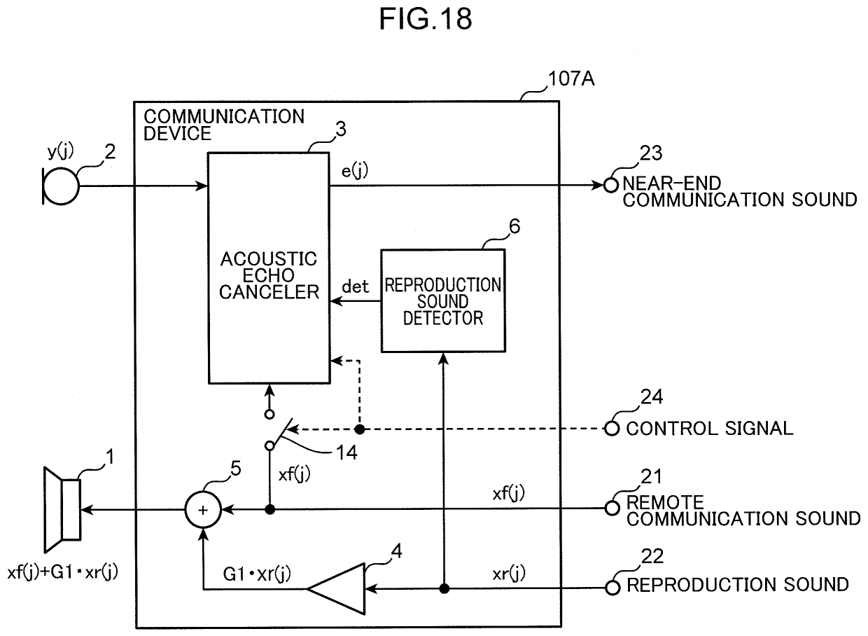

FIG. 18 is a diagram showing a configuration of a communication system in the eighth embodiment of the present disclosure.

The communication system shown in FIG. 18 includes the speaker 1, the microphone 2, a communication sound input part 21, a reproduction sound input part 22, a communication sound output part 23, a control signal input part 24, and a communication device 107A. In the eighth embodiment, elements which are the same as those in the first embodiment are given the same reference signs and numerals, and thus, descriptions therefor will be omitted.

The control signal input part 24 outputs, to the communication device 107A, a control signal indicating whether to return a remote communication sound to a remote location. The control signal is sent from a remote communication device (not shown) at a receiver. The control signal input part 24 is connected to a communicator (not shown). The communicator is configured to receive a control signal from the remote supervising device at the receiver via a network. The remote supervising device receives an input from the remote utterer as to whether to return the remote communication sound to the remote location.

The communication device 107A includes an acoustic echo canceler 3, a first amplifier 4, a first adder 5, a reproduction sound detector 6, and a reference change switch 14. The communication device 107A shown in FIG. 18 additionally includes the reference change switch 14 between the communication sound input part 21 and the acoustic echo canceler 3 in comparison with the communication device 100 shown in FIG. 1, and the remaining configuration is the same as the configuration shown in FIG. 1. The communication device 107A may include at least one of the speaker 1 and the microphone 2.

The reference change switch 14 switches, on the basis of the control signal indicating whether to return the remote communication sound to the remote location, between an ON-mode of inputting the remote communication sound as a reference signal into the acoustic echo canceler 3 and an OFF-mode of avoiding the inputting of the remote communication sound as the reference signal into the acoustic echo canceler 3. The ON/OFF-mode of the reference change switch 14 is changed in response to the control signal input from the control signal input part 24. Normally, the reference change switch 14 is set to the ON-mode.

The reference change switch 14 switches to the OFF-mode when the control signal indicates returning of the remote communication sound to the remote location. Specifically, when the remote utterer confirms that the remote communication sound is loudly produced at a destination, the control signal input part 24 acquires a control signal for setting the reference change switch 14 to the OFF-mode. In this manner, the reference change switch 14 is set to the OFF-mode.

When the reference change switch 14 is set to the ON-mode, the acoustic echo canceler 3 removes the remote communication sound. In this case, the remote utterer cannot hear the remote communication sound loudly reproduced at the destination. In contrast, when the reference change switch 14 is set to the OFF-mode, the acoustic echo canceler 3 avoids the removing of the remote communication sound. In this case, the remote utterer can hear the remote communication sound loudly produced at the destination.

When the reference change switch 14 is set to the OFF-mode, the acoustic echo canceler 3 receives an input of “0” to serve as the reference signal therefor in place of the remote communication sound xf(j). This consequently suspends an update of a coefficient of an adaptive filter of the acoustic echo canceler 3.

Conclusively, the reference change switch 14 switches to the OFF-mode of avoiding the inputting of a remote communication sound into the acoustic echo canceler as a reference signal when a control signal indicates returning of the remote communication sound to a remote location. The configuration thus keeps the acoustic echo canceler 3 from removing the remote communication sound and enables the remote utterer to confirm that the communication sound of the remote utterer is loudly produced at a destination.

### Ninth Embodiment

A communication device according to the ninth embodiment is configured to loudly produce a remote communication sound from a speaker 1 and return the remote communication sound collected by a microphone 2 to a remote communication device at a receiver in the same manner as the communication device according to the eighth embodiment.

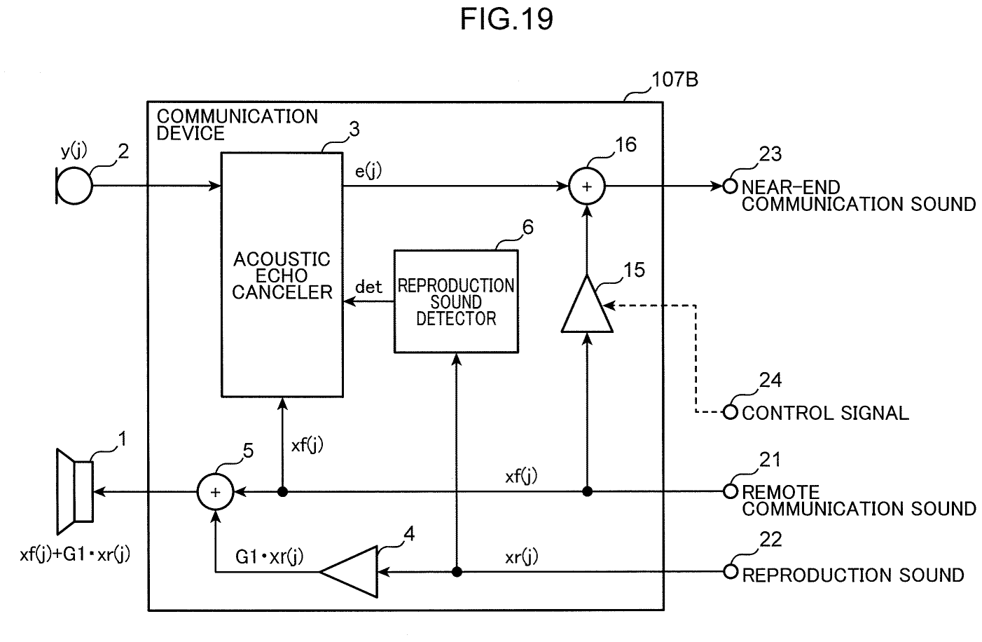

FIG. 19 is a diagram showing a configuration of a communication system in the ninth embodiment of the present disclosure.

The communication system shown in FIG. 19 includes the speaker 1, the microphone 2, a communication sound input part 21, a reproduction sound input part 22, a communication sound output part 23, a control signal input part 24, and a communication device 107B. In the ninth embodiment, elements which are the same as those in the first embodiment are given the same reference signs and numerals, and thus, descriptions therefor will be omitted.

The control signal input part 24 outputs, to the communication device 107B, a control signal indicating whether to return a remote communication sound to a remote utterer. The control signal is sent from a remote communication device (not shown) at a receiver. The control signal input part 24 is connected to a communicator (not shown). The communicator is configured to receive a control signal from the remote supervising device at the receiver via a network. The remote supervising device receives an input from the remote utterer as to whether to return the remote communication sound to the remote location.

The communication device 107B includes an acoustic echo canceler 3, a first amplifier 4, a first adder 5, a reproduction sound detector 6, a fourth amplifier 15, and a fourth adder 16. The communication device 107B shown in FIG. 19 additionally includes the fourth adder 16 between the acoustic echo canceler 3 and the communication sound output part 23, and the fourth amplifier 15 between the communication sound input part 21 and the fourth adder 16 in comparison with the communication device 100 shown in FIG. 1, and the remaining configuration is the same as the configuration shown in FIG. 1. The communication device 107B may include at least one of the speaker 1 and the microphone 2.

The fourth amplifier 15 adjusts, on the basis of the control signal indicating whether to return the remote communication sound to the remote location, a sound volume of the remote communication sound to be input into the fourth adder 16. The fourth amplifier 15 serves as an example third sound volume adjuster. The fourth amplifier 15 adjusts, on the basis of the control signal from the control signal input part 24, the sound volume of the remote communication sound from the communication sound input part 21. The fourth amplifier 15 adjusts the remote communication sound to a sound volume which is audible to the remote utterer when the control signal indicates returning of the remote communication sound to the remote location. The fourth amplifier 15 adjusts the remote communication sound to a sound volume which is inaudible to the remote utterer when the control signal indicates avoiding the returning of the remote communication sound to the remote location.

The fourth amplifier 15 changes a gain in response to the control signal input from the control signal input part 24. The fourth amplifier 15 multiplies the remote communication sound from the communication sound input part 21 by a predetermined gain G4 when the control signal indicates returning of the remote communication sound to the remote location. The gain G4 is determined in advance so that an uttering sound of a near-end utterer and a remote communication sound become equivalent to each other at a remote location. When the control signal does not indicate the returning of the remote communication sound to the remote location, the fourth amplifier 15 multiplies the remote communication sound from the communication sound input part 21 by “0” to mute the remote communication sound.

The fourth adder 16 adds an output signal from the fourth amplifier 15 and an output signal from the acoustic echo canceler 3. The fourth adder 16 serves as an example third adder. When the control signal indicates the returning of the remote communication sound to the remote location, the fourth adder 16 adds the remote communication sound having a sound volume amplified by the fourth amplifier 15 to an output signal from the acoustic echo canceler 3. When the control signal indicates avoiding the returning of the remote communication sound to the remote location, the fourth adder 16 avoids adding the remote communication sound to the output signal from the acoustic echo canceler 3.

Conclusively, this configuration achieves adjustment of a remote communication sound to a sound volume which is audible to a remote utterer when a control signal indicates returning of the communication sound to a remote location. The configuration in which the communication sound having the sound volume adjusted to be audible to the remote utterer by the fourth amplifier 15 is added to an output signal from the acoustic echo canceler 3 enables the remote utterer to confirm that the remote communication sound of the remote utterer is loudly produced at a destination.

### Tenth Embodiment

A communication device according to the tenth embodiment is configured to loudly produce a remote communication sound from a speaker 1 and returns the remote communication sound collected by a microphone 2 to a remote communication device at a receiver in the same manner as the communication device according to each of the eighth embodiment and the ninth embodiment.

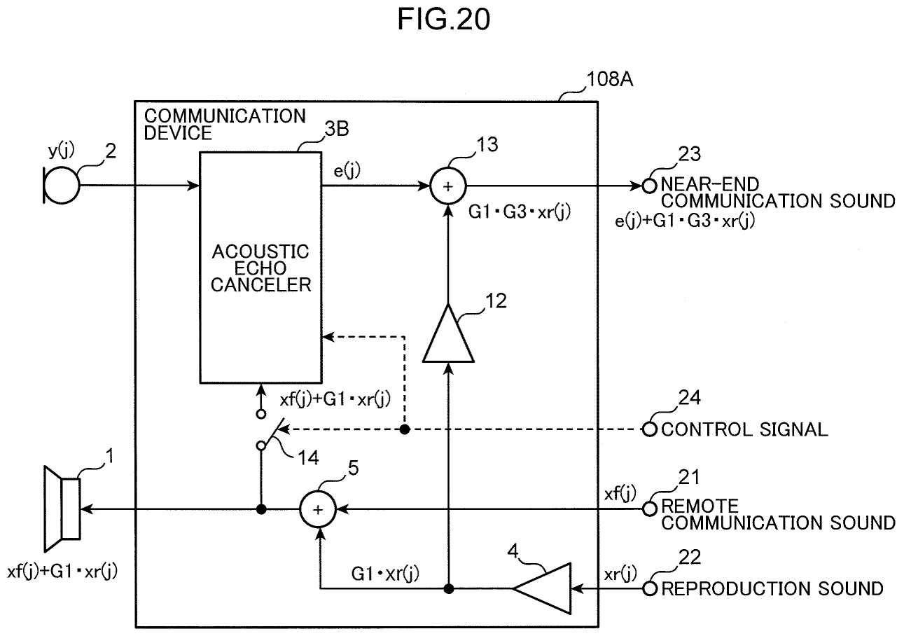

FIG. 20 is a diagram showing a configuration of a communication system in the tenth embodiment of the present disclosure.

The communication system shown in FIG. 20 includes the speaker 1, the microphone 2, a communication sound input part 21, a reproduction sound input part 22, a communication sound output part 23, a control signal input part 24, and a communication device 108A. In the tenth embodiment, elements which are the same as those in the first embodiment and the seventh embodiment are given the same reference signs and numerals, and thus explanation therefor will be omitted.

The control signal input part 24 outputs, to the communication device 108A, a control signal indicating whether to return a remote communication sound to a remote location. The control signal is sent from a remote communication device (not shown) at a receiver. The control signal input part 24 is connected to a communicator (not shown). The communicator is configured to receive a control signal from the remote supervising device at the receiver via a network. The remote supervising device receives an input from the remote utterer as to whether to return the remote communication sound to the remote location.

The communication device 108A includes an acoustic echo canceler 3B, a first amplifier 4, a first adder 5, a third amplifier 12, a third adder 13, and a reference change switch 14. The communication device 108A shown in FIG. 20 additionally includes the reference change switch 14 between the first adder 5 and the acoustic echo canceler 3B in comparison with the communication device 106 shown in FIG. 16, and the remaining configuration is the same as the configuration shown in FIG. 16. The communication device 108A may include at least one of the speaker 1 and the microphone 2.

The reference change switch 14 switches, on the basis of the control signal indicating whether to return the remote communication sound to the remote location, between an ON-mode of inputting an output signal from the first adder 5 as a reference signal into the acoustic echo canceler 3B and an OFF-mode of avoiding the inputting of the output signal from the first adder 5 as the reference signal into the acoustic echo canceler 3B. The ON/OFF-mode of the reference change switch 14 is changed in response to the control signal input from the control signal input part 24. Normally, the reference change switch 14 is set to the ON-mode.

The reference change switch 14 switches to the OFF-mode when the control signal indicates returning of the remote communication sound to the remote location. Specifically, when the remote utterer confirms that the remote communication sound is loudly produced at the destination, the control signal input part 24 acquires a control signal for setting the reference change switch 14 to the OFF-mode. In this manner, the reference change switch 14 is set to the OFF-mode.

When the reference change switch 14 is set to the ON-mode, the acoustic echo canceler 3B removes an output signal xf(j)+G1·xr(j) from the first adder 5. In this case, the remote utterer cannot hear the remote communication sound loudly reproduced at the destination. In contrast, when the reference change switch 14 is set to the OFF-mode, the acoustic echo canceler 3B avoids removing the output signal xf(j)+G1·xr(j) from the first adder 5. In this case, the remote utterer can hear the remote communication sound loudly produced at the destination.

When the reference change switch 14 is set to the OFF-mode, the acoustic echo canceler 3B receives an input of “0” to serve as the reference signal therefor in place of the output signal xf(j)+G1·xr(j) from the first adder 5. This consequently suspends an update of a coefficient of an adaptive filter of the acoustic echo canceler 3B.

Conclusively, the reference change switch 14 switches to the OFF-mode of avoiding inputting of an output signal from the first adder 5 into the acoustic echo canceler 3B as a reference signal when a control signal indicates returning of the remote communication sound to a remote location. The configuration thus keeps the acoustic echo canceler 3B from removing the remote communication sound and enables the remote utterer to confirm that the communication sound of the remote utterer is loudly produced at a destination.

### Eleventh Embodiment

A communication device according to the eleventh embodiment is configured to loudly produce a remote communication sound from a speaker 1 and return the remote communication sound collected by a microphone 2 to a remote communication device at a receiver in the same manner as the communication device according to each of the eighth embodiment to the tenth embodiment.

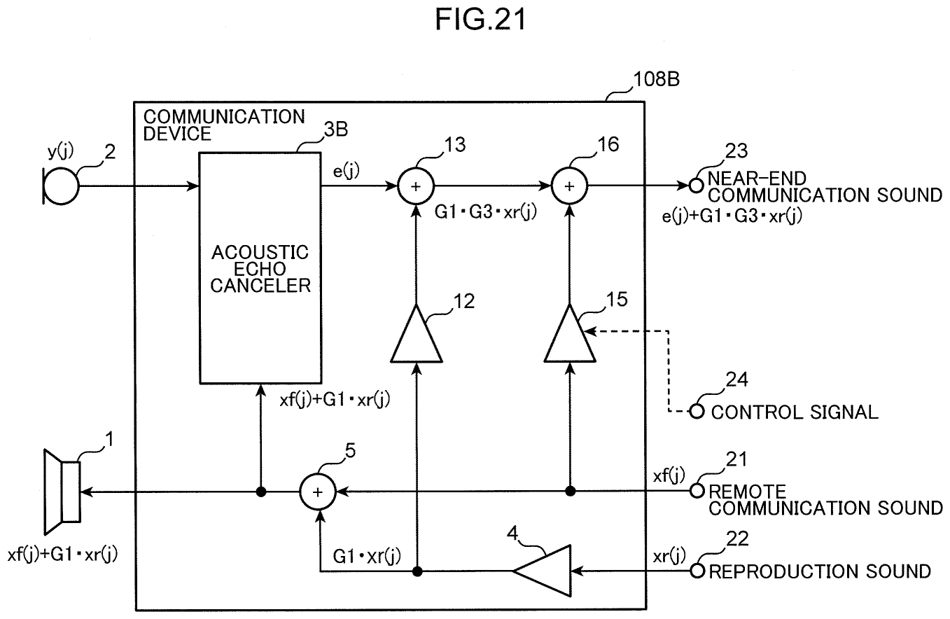

FIG. 21 is a diagram showing a configuration of a communication system in the eleventh embodiment of the present disclosure.

The communication system shown in FIG. 21 includes the speaker 1, the microphone 2, a communication sound input part 21, a reproduction sound input part 22, a communication sound output part 23, a control signal input part 24, and a communication device 108B. In the eleventh embodiment, elements which are the same as those in the first embodiment and the seventh embodiment are given the same reference signs and numerals, and thus, explanation therefor will be omitted.

The control signal input part 24 outputs, to the communication device 108B, a control signal indicating whether to return a remote communication sound to a remote location. The control signal is sent from a remote communication device (not shown) at a receiver. The control signal input part 24 is connected to a communicator (not shown). The communicator is configured to receive a control signal from the remote supervising device at the receiver via a network. The remote supervising device receives an input from the remote utterer as to whether to return the remote communication sound to the remote location.

The communication device 108B includes an acoustic echo canceler 3B, a first amplifier 4, a first adder 5, a third amplifier 12, a third adder 13, a fourth amplifier 15, and a fourth adder 16. The communication device 108B shown in FIG. 21 additionally includes the fourth adder 16 between the third adder 13 and the communication sound output part 23, and the fourth amplifier 15 between the communication sound input part 21 and the fourth adder 16 in comparison with the communication device 106 shown in FIG. 16, and the remaining configuration is the same as the configuration shown in FIG. 16. The communication device 108B may include at least one of the speaker 1 and the microphone 2.

The fourth amplifier 15 adjusts, on the basis of the control signal indicating whether to return the remote communication sound to the remote location, a sound volume of the remote communication sound to be input into the fourth adder 16. The fourth amplifier 15 serves as an example third sound volume adjuster. The fourth amplifier 15 adjusts, on the basis of the control signal from the control signal input part 24, the sound volume of the remote communication sound from the communication sound input part 21. The fourth amplifier 15 adjusts the communication sound to a sound volume which is audible to a remote utterer when the control signal indicates returning of the remote communication sound to the remote location. The fourth amplifier 15 adjusts the communication sound to a sound volume which is inaudible to the remote utterer when the control signal indicates avoiding the returning of the remote communication sound to the remote location.

The fourth amplifier 15 changes a gain in response to the control signal input from the control signal input part 24. The fourth amplifier 15 multiplies the remote communication sound from the communication sound input part 21 by a predetermined gain G4 when the control signal indicates returning of the remote communication sound to the remote location. The gain G4 is determined in advance so that an uttering sound of a near-end utterer and a remote communication sound become equivalent to each other at a remote location. When the control signal does not indicate the returning of the remote communication sound to the remote location, the fourth amplifier 15 multiplies the remote communication sound from the communication sound input part 21 by “0” to mute the remote communication sound.

The fourth adder 16 adds an output signal from the fourth amplifier 15 and an output signal e(j)+G1·G3·xr(j) from the third adder 13. The fourth adder 16 serves as an example third adder. When the control signal indicates returning of the remote communication sound to the remote location, the fourth adder 16 adds the remote communication sound having a sound volume amplified by the fourth amplifier 15 to the output signal from the third adder 13. When the control signal indicates avoiding the returning of the remote communication sound to the remote location, the fourth adder 16 avoids adding the remote communication sound to the output signal from the third adder 13.

Conclusively, this configuration achieves adjustment of a remote communication sound to a sound volume which is audible to a remote utterer when a control signal indicates returning of the remote communication sound to a remote location. The configuration in which the remote communication sound having the sound volume adjusted by the fourth amplifier 15 to be audible to the remote utterer is added to an output signal from the third adder 13 hence enables the remote utterer to confirm that the remote communication sound of the remote utterer is loudly produced at a destination.

Next, a configuration of: a vehicle including the communication device 100 according to the first embodiment; and a remote supervising device will be described.

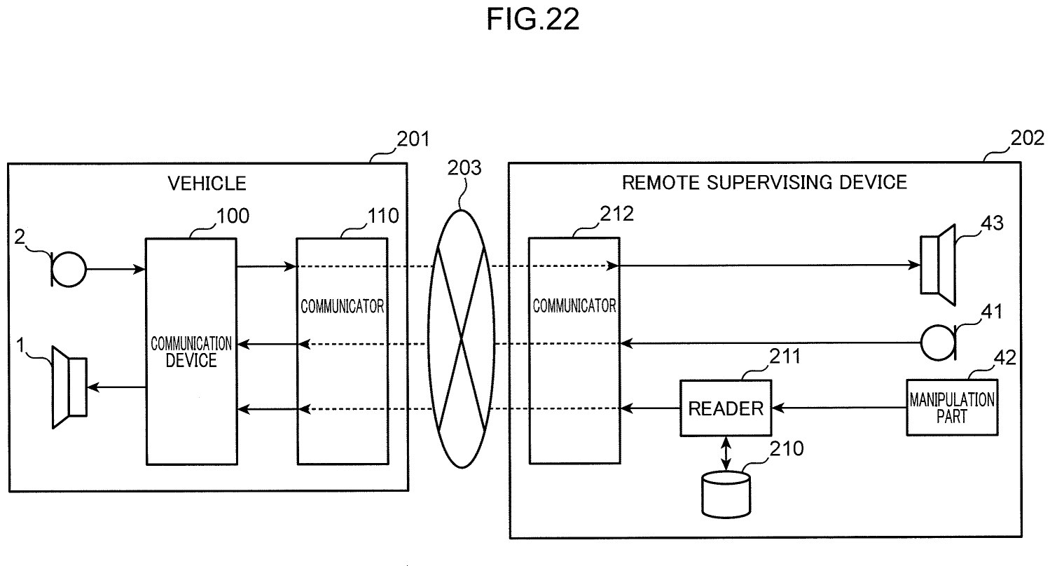

FIG. 22 is a diagram showing a configuration of: a vehicle 201 including the communication device 100 according to the first embodiment; and a remote supervising device 202.

The vehicle 201 includes a speaker 1, a microphone 2, the communication device 100, and a communicator 110. In FIG. 22, elements which are the same as those in the first embodiment are given the same reference signs and numerals, and thus, descriptions therefor will be omitted. Alternatively, the vehicle 201 may include any of the communication devices 101 to 108B according to the second to eleventh embodiments in place of the communication device 100 according to the first embodiment.

The communicator 110 includes a communication sound input part 21, a reproduction sound input part 22, and a communication sound output part 23.

The communicator 110 receives a remote communication sound of a remote supervisor sent from the remote supervising device 202. The communicator 110 outputs the received remote communication sound to the communication device 100. The communicator 110 sends, to the remote supervising device 202, a near-end communication sound output from the communication device 100. The near-end communication sound serves as a sound signal including an echo of each of the communication sound of a near-end utterer and the reproduction sound, and excluding an echo component of the remote communication sound. The communicator 110 receives the reproduction sound sent from the remote supervising device 202. The communicator 110 outputs the received reproduction sound to the communication device 100. The communication device 100 may include the communicator 110.

The vehicle 201 and the remote supervising device 202 are communicably connected to each other via a network 203. The network 203 includes, for example, the internet or a mobile phone network.

The remote supervising device 202 includes a microphone 41, a manipulation part 42, a speaker 43, a storage part 210, a reader 211, and a communicator 212. The remote supervising device 202 serves as an example remote communication device.

The microphone 41 collects a sound of a remote supervisor. The microphone 41 outputs a remote communication sound representing the collected sound to the communicator 212.

Examples of the manipulation part 42 include a keyboard, a mouse, and a touch screen to receive an input manipulation from the remote supervisor. The manipulation part 42 receives selection of a reproduction sound by the remote supervisor to be output to the outside of the vehicle 201 from among a plurality of reproduction sounds.

The manipulation part 42 may further receive an input of control information about a remote control of the vehicle 201. The remote supervisor uses the manipulation part 42 to move the vehicle 201.

The storage part 210 stores the plurality of reproduction sounds in advance.

The reader 211 reads out the reproduction sound selected via the manipulation part 42 from among the reproduction sounds stored in the storage part 210.

The communicator 212 sends, to the vehicle 201, the remote communication sound output from the microphone 41. The communicator 212 receives the near-end communication sound sent from the vehicle 201, and outputs the near-end communication sound to the speaker 43. The communicator 212 sends the reproduction sound read out by the reader 211 to the vehicle 201.

The speaker 43 loudly produces the near-end communication sound sent from the vehicle 201.

As illustrated in FIG. 22, the communication device 100 may acquire a reproduction sound sent from the remote supervising device 202.

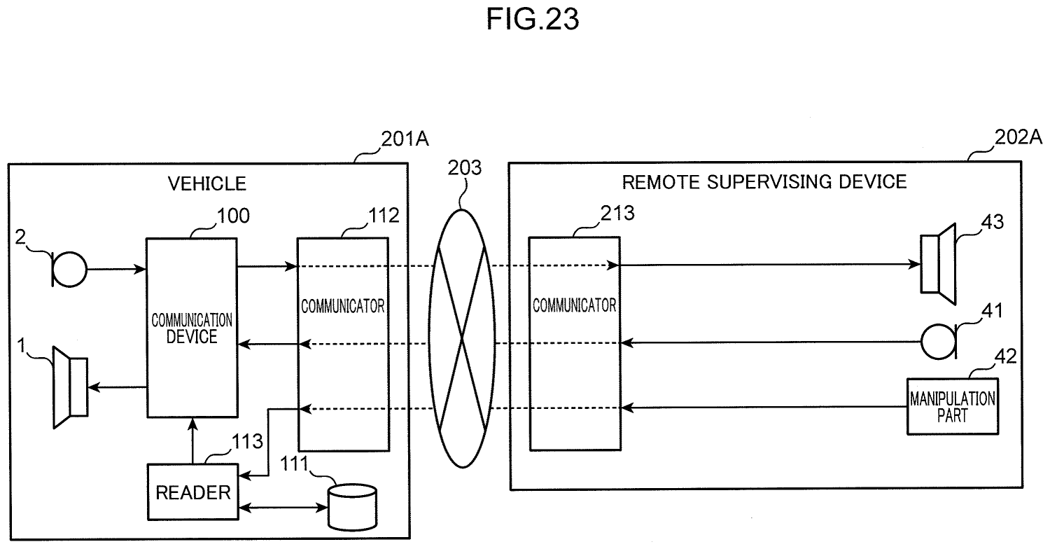

FIG. 23 is a diagram showing another configuration of: a vehicle 201A including the communication device 100 according to the first embodiment; and a remote supervising device 202A.

The vehicle 201A includes a speaker 1, a microphone 2, the communication device 100, a storage part 111, a communicator 112, and a reader 113. In FIG. 23, elements which are the same as those in the first embodiment are given the same reference signs and numerals, and thus, descriptions therefor will be omitted. Alternatively, the vehicle 201A may include any of the communication devices 101 to 108B according to the second to eleventh embodiments in place of the communication device 100 according to the first embodiment.

The storage part 111 stores a plurality of reproduction sounds in advance.

The communicator 112 includes a communication sound input part 21 and a communication sound output part 23.

The communicator 112 receives a remote communication sound of a remote supervisor sent from the remote supervising device 202A. The communicator 112 outputs the received remote communication sound to the communication device 100. The communicator 112 sends, to the remote supervising device 202A, a near-end communication sound output from the communication device 100. The near-end communication sound serves as a sound signal including an echo of each of the communication sound of a near-end utterer and the reproduction sound, and excluding an echo component of the remote communication sound. The communicator 112 receives, from the remote supervising device 202A, reproduction information designating a reproduction sound to be output among the reproduction sounds.

The reader 113 reads out, from the storage part 111, the reproduction sound designated by the reproduction information received by the communicator 112. The reader 113 outputs the read-out reproduction sound to the communication device 100. The reader 113 includes a reproduction sound input part 22.

The communication device 100 may include the storage part 111, the communicator 112, and the reader 113.

The vehicle 201A and the remote supervising device 202A are communicably connected to each other via a network 203. The network 203 includes, for example, the internet.

The remote supervising device 202A includes a microphone 41, a manipulation part 42, a speaker 43, and a communicator 213. The remote supervising device 202A serves as an example remote communication device. The microphone 41 and the speaker 43 shown in FIG. 23 correspond to the microphone 41 and the speaker 43 shown in FIG. 22.

Examples of the manipulation part 42 include a keyboard, a mouse, and a touch screen to receive an input manipulation from the remote supervisor. The manipulation part 42 receives selection of a reproduction sound by the remote supervisor to be output to the outside of the vehicle 201A from among the reproduction sounds.

The communicator 213 sends, to the vehicle 201A, a remote communication sound output from the microphone 41. The communicator 213 receives the near-end communication sound sent from the vehicle 201A, and outputs the near-end communication sound to the speaker 43. The communicator 213 sends, to the vehicle 201A, reproduction information designating a reproduction sound selected, from among the reproduction sounds, by the manipulation part 42 to be output from the vehicle 201A.

As illustrated in FIG. 23, the communication device 100 may acquire a reproduction sound stored in the vehicle 201A or the communication device 100 in advance.

In the embodiments, each constituent element may be realized with dedicated hardware or by executing a software program suitable for the constituent element. Each constituent element may be realized by a program execution unit, such as a CPU or a processor, reading out and executing a software program recorded on a recording medium, such as a hard disk or a semiconductor memory. Other independent computer system may establish a program by recording the program in a recording medium to be transferred, or transferring the program via a network.

A part of or a whole of the functions of the device according to each embodiment of the disclosure is typically realized as a large scale integration (LSI), which is an integrated circuit. These functions may be formed as separate chips, or some of or a whole of the functions may be included in one chip. The circuit integration is not limited to the LSI, and may be realized with a dedicated circuit or a general-purpose processor. A field programmable gate array (FPGA) that is programmable after manufacturing of an LSI or a reconfigurable processor in which connections and settings of circuit cells within the LSI are reconfigurable may be used.

A part of or a whole of the functions of the device according to each embodiment of the present disclosure may be implemented by a processor, such as a CPU executing a program.

Numerical values used above are merely illustrative to be used to specifically describe the present disclosure, and thus the present disclosure is not limited to the illustrative numerical values.

Order in which steps shown in the flowcharts are executed is merely illustrative to be used to specifically describe the present disclosure, and thus steps may be executed in order other than the above order as long as similar effects are obtained. Some of the steps may be executed simultaneously with (in parallel to) other steps.

The technology according to the present disclosure achieves cancelation of an acoustic echo attributed to loud producing of a communication sound of a remote utterer, and enables the remote utterer to confirm whether the reproduction sound is loudly produced. The technology is thus useful as a technology of loudly producing a predetermined reproduction sound to a vicinity and enabling a person in the vicinity and a remote utterer to communicate with each other.

1. A communication device that is configured to loudly produce a predetermined reproduction sound to a vicinity and enables a person in the vicinity and a remote utterer to communicate with each other, the communication device comprising:
a first adder that adds the reproduction sound to a communication sound of the remote utterer and outputs the communication sound additionally including the reproduction sound to a speaker; and
an acoustic echo canceler that cancels, on the basis of the communication sound to serve as a reference signal, an echo component of the communication sound contained in an input signal acquired by a microphone configured to collect a sound in the vicinity.

2. The communication device according to claim 1, further comprising:
a reproduction sound detector that detects presence or absence of the reproduction sound, wherein
the acoustic echo canceler suspends an update of a filter coefficient of an adaptive filter when the reproduction sound detector detects the reproduction sound.

3. The communication device according to claim 1, further comprising:
a first sound volume adjuster that adjusts a sound volume of the reproduction sound and outputs the reproduction sound having the adjusted sound volume to the first calculator.

4. The communication device according to claim 1, further comprising:
an automatic gain controller that automatically adjusts a sound volume indicated by an output signal from the acoustic echo canceler.

5. The communication device according to claim 2, further comprising:
a lowering gain setter that sets a first lowering gain for lowering a sound volume indicated by an output signal from the acoustic echo canceler when the reproduction sound detector detects the reproduction sound, and sets a second lowering gain for avoiding the lowering of the sound volume indicated by the output signal from the acoustic echo canceler when the reproduction sound detector does not detect the reproduction sound; and
a variable amplifier that multiplies the output signal from the acoustic echo canceler by the first lowering gain or the second lowering gain set by the lowering gain setter.

6. The communication device according to claim 1, further comprising:
a sound volume lowering part that lowers a sound volume of the reproduction sound; and
a second adder that adds the reproduction sound having the sound volume lowered by the sound volume lowering part to the communication sound, wherein
the acoustic echo canceler cancels, on the basis of an output signal from the second adder to be a reference signal, the echo component of the communication sound and an echo component of the reproduction sound having the lowered sound volume contained in the input signal acquired by the microphone.

7. The communication device according to claim 6, further comprising:
a reproduction sound detector that detects presence or absence of the reproduction sound, wherein
the acoustic echo canceler suspends an update of a filter coefficient of an adaptive filter when the reproduction sound detector detects the reproduction sound.

8. The communication device according to claim 7, further comprising:
a lowering gain setter that estimates an echo cancelation amount of the acoustic echo canceler and sets a first lowering gain for lowering a sound volume indicated by an output signal from the acoustic echo canceler in association with the estimated echo cancelation amount when the reproduction sound detector detects the reproduction sound, and sets a second lowering gain for avoiding the lowering of the sound volume indicated by the output signal from the acoustic echo canceler when the reproduction sound detector does not detect the reproduction sound; and
a variable amplifier that multiplies the output signal from the acoustic echo canceler by the first lowering gain or the second lowering gain set by the lowering gain setter.

9. The communication device according to claim 8, wherein the lowering gain setter calculates a power value of the filter coefficient and estimates the echo cancelation amount from the calculated power value of the filter coefficient.

10. The communication device according to claim 8, wherein the lowering gain setter estimates the echo cancelation amount on the basis of a level of the input signal input into the acoustic echo canceler from the microphone and a level of the output signal from the acoustic echo canceler.

11. The communication device according to claim 1, wherein the acoustic echo canceler cancels, on the basis of an output signal from the first adder to be a reference signal, the echo component of the communication sound and an echo component of the reproduction sound contained in the input signal acquired by the microphone, the communication device further comprising:
a second adder that adds the reproduction sound to an output signal from the acoustic echo canceler.

12. The communication device according to claim 11, further comprising:
a second sound volume adjuster that adjusts a sound volume of the reproduction sound, wherein
the second adder adds the reproduction sound having the sound volume adjusted by the second sound volume adjuster to the output signal from the acoustic echo canceler.

13. The communication device according to claim 1, further comprising:
a switch that switches, on the basis of a control signal indicating whether to return the communication sound to a remote location, between an ON-mode of inputting the communication sound as the reference signal into the acoustic echo canceler and an OFF-mode of avoiding the inputting of the communication sound as the reference signal into the acoustic echo canceler, wherein
the switch switches to the OFF-mode when the control signal indicates returning of the communication sound to the remote location.

14. The communication device according to claim 1, further comprising:
a third adder that adds the communication sound to an output signal from the acoustic echo canceler; and
a third sound volume adjuster that adjusts, on the basis of a control signal indicating whether to return the communication sound to a remote location, a sound volume of the communication sound to be input into the third adder, wherein
the third sound volume adjuster adjusts the communication sound to a sound volume which is audible to the remote utterer when the control signal indicates returning of the communication sound to the remote location, and adjusts the communication sound to a sound volume which is inaudible to the remote utterer when the control signal indicates avoiding the returning of the communication sound to the remote location.

15. The communication device according to claim 11, further comprising:
a switch that switches, on the basis of a control signal indicating whether to return the communication sound to a remote location, between an ON-mode of inputting an output signal from the first adder as the reference signal into the acoustic echo canceler and an OFF-mode of avoiding the inputting of the output signal from the first adder as the reference signal into the acoustic echo canceler, wherein
the switch switches to the OFF-mode when the control signal indicates returning of the communication sound to the remote location.

16. The communication device according to claim 11, further comprising:
a third adder that adds the communication sound to an output signal from the second adder; and
a third sound volume adjuster that adjusts, on the basis of a control signal indicating whether to return the communication sound to a remote location, a sound volume of the communication sound to be input into the third adder, wherein
the third sound volume adjuster adjusts the communication sound to a sound volume which is audible to the remote utterer when the control signal indicates returning of the communication sound to the remote location, and adjusts the communication sound to a sound volume which is inaudible to the remote utterer when the control signal indicates avoiding the returning of the communication sound to the remote location.

17. The communication device according to claim 1, further comprising:
a storage part that stores a plurality of the reproduction sounds in advance;
a communicator that receives, from a remote communication device, reproduction information designating a reproduction sound to be output among the reproduction sounds; and
a reader that reads out the reproduction sound designated by the reproduction information from the storage part.

18. The communication device according to claim 1, further comprising:
a communicator that receives the reproduction sound sent from a remote communication device.

19. A communication method for a communication device that is configured to loudly produce a predetermined reproduction sound to a vicinity and enables a person in the vicinity and a remote utterer to communicate with each other, the communication method comprising:
adding the reproduction sound to a communication sound of the remote utterer and outputting the communication sound additionally including the reproduction sound to a speaker; and
canceling, on the basis of the communication sound to serve as a reference signal, an echo component of the communication sound contained in an input signal acquired by a microphone configured to collect a sound in the vicinity.

20. A non-transitory computer readable recording medium storing a communication program for loudly producing a predetermined reproduction sound to a vicinity and enabling a person in the vicinity and a remote utterer to communicate with each other, the communication program comprising:
causing a computer to serve as:
a first adder that adds the reproduction sound to a communication sound of the remote utterer and outputs the communication sound additionally including the reproduction sound to a speaker; and
an acoustic echo canceler that cancels, on the basis of the communication sound to serve as a reference signal, an echo component of the communication sound contained in an input signal acquired by a microphone configured to collect a sound in the vicinity.
